(19) United States
(12) Patent Application Publication
(10) Pub. No.: US 2026/0271575 A1
(43) Pub. Date: Sep. 10, 2026

(54) DISPLAY DEVICE AND ELECTRONIC DEVICE INCLUDING THE SAME

(71) Applicant: Samsung Display Co., Ltd., Yongin-Si (KR)

(72) Inventors: Hyeon Sik KIM, Yongin-si (KR); Gun Hee KIM, Yongin-si (KR); Jung Woo PARK, Yongin-si (KR); Kwang Soo BAE, Yongin-si (KR); Tae Kyung AHN, Yongin-si (KR)

(21) Appl. No.: 19/389,046

(22) Filed: Nov. 14, 2025

(30) Foreign Application Priority Data
Mar. 4, 2025 (KR) 10-2025-0027391
Jul. 11, 2025 (KR) 10-2025-0093511

(51) Int. Cl. H10K 59/38; H10K 59/126; H10K 59/60; H10K 102/00

(52) U.S. Cl. CPC H10K 59/38; H10K 59/126; H10K 59/60; H10K 2102/331

(57) ABSTRACT

A display device is presented. The display device includes a substrate; a circuit layer disposed on the substrate; an element layer disposed on the circuit layer, wherein the element layer includes a light-emitting element configured to emit first light having a first wavelength, a light-receiving element positioned to receive and sense second light having a second wavelength, and a pixel defining film patterned to define each of the light-emitting element and the light-receiving element; and a light conversion layer disposed on the element layer and including a light conversion pattern overlapping the pixel defining film, wherein the light conversion pattern converts the first light emitted from the light-emitting element into the second light, wherein the light-receiving element is positioned to receive the second light obtained via the light conversion of the light conversion pattern.

### CROSS-REFERENCE TO RELATED APPLICATIONS

This application claims priority from Korean Patent Application No. 10-2025-0027391 filed on Mar. 4, 2025 and Korean Patent Application No. 10-2025-0093511 filed on Jul. 11, 2025 in the Korean Intellectual Property Office, and all the benefits accruing therefrom under 35 U.S.C. 119, the contents of which in its entirety are herein incorporated by reference.

### BACKGROUND

### Field

The present disclosure relates to a display device and an electronic device including the same.

### Description of Related Art

In today’s information-oriented society, demand for a display device for displaying an image is increasing in various forms. The display device may be a display device such as a liquid crystal display device, a field emission display device, a light-emitting display device, or the like. The light-emitting display device may include an organic light-emitting display device including an organic light-emitting diode element as a light-emitting element, or an inorganic light-emitting display device including an inorganic light-emitting diode element as a light-emitting element, or the like.

The display device may include various optical devices, such as an image sensor for capturing an image in front of the display device, a proximity sensor for detecting whether a user is positioned close to a front surface of the display device, an illuminance sensor for detecting illuminance of the front surface of the display device, an iris sensor for recognizing an iris of the user, and a fingerprint sensor for recognizing a fingerprint of the user. Such an optical device may be provided separately from the display panel, or may be embedded in the display panel.

### SUMMARY

A purpose of the present disclosure is to provide a display device having high resolution including a light-emitting element and a light-receiving element, and an electronic device including the same.

The technical purposes of the present disclosure are not limited to the above-mentioned technical purposes, and other technical purposes not mentioned may be clearly understood by a person skilled in the art of the present disclosure from the following description.

According to one or more embodiments of the disclosure, a display device includes a substrate; a circuit layer disposed on the substrate; an element layer disposed on the circuit layer, wherein the element layer includes a light-emitting element configured to emit first light having a first wavelength, a light-receiving element configured to sense second light having a second wavelength, and a pixel defining film patterned to define each of the light-emitting element and the light-receiving element; and a light conversion layer disposed on the element layer and including a light conversion pattern overlapping the pixel defining film, wherein the light conversion pattern converts the first light emitted from the light-emitting element into the second light, wherein the light-receiving element is positioned to receive and sense the second light.

In an embodiment, the light conversion pattern may be disposed to surround the light-emitting element in a plan view of the display device.

In an embodiment, at least a portion of the light conversion pattern may be disposed between the light-emitting element and the light-receiving element in a plan view of the display device.

In an embodiment, the light conversion pattern may have an opening defined therein above the light-emitting element.

In an embodiment, a size of the opening may be larger than a size of the light-emitting element in plan view.

In an embodiment, the display device may further comprise a color filter disposed on the light conversion layer and transmitting the first light, wherein a first portion of the color filter overlaps the opening and the light-emitting element.

In an embodiment, a second portion of the color filter overlaps the light-receiving element and may transmit the second light.

In an embodiment, a distance between one end of the light conversion pattern and the light-emitting element may be smaller than a distance between the other end of the light conversion pattern and the light-receiving element.

In an embodiment, the light conversion layer include a light blocking film constructed to absorb or block the first light, wherein the light blocking film may be disposed at one end of the light conversion pattern adjacent to the light-receiving element.

In an embodiment, the light conversion pattern may include a base resin and a wavelength conversion material, wherein the wavelength conversion material includes at least one of a quantum dot, a quantum rod, and phosphor.

In an embodiment, the display device may further comprise a light blocking layer disposed on the light conversion layer and has light-transmissive openings defined therein, wherein each of the light-transmissive openings is positioned above one of the light-emitting element and the light-receiving element.

In an embodiment, the first light may be visible light and the second light is infrared light.

According to one or more embodiments of the disclosure, a display device includes a substrate; a circuit layer disposed on the substrate; an element layer disposed on the circuit layer, wherein the element layer includes: a first light-emitting element configured to emit first light having a first wavelength; a second light-emitting element configured to emit second light having a second wavelength; a third light-emitting element configured to emit third light having a third wavelength; a light-receiving element configured to sense fourth light having a fourth wavelength; and a pixel defining film patterned to define each of the first to third light-emitting elements and the light-receiving element; and a light conversion layer disposed on the element layer and including a first light conversion pattern overlapping the pixel defining film, wherein the first light conversion pattern is disposed to surround the first light-emitting element in a plan view of the display device, wherein the first light conversion pattern converts the first light emitted from the first light-emitting element into the fourth light, wherein the light-receiving element is configured to sense the fourth light obtained via light conversion of the first light conversion pattern.

In an embodiment, the light conversion layer may further include at least one of a second light conversion pattern or a third light conversion pattern overlapping the pixel defining film, wherein the second light conversion pattern is disposed to surround the second light-emitting element in the plan view, wherein the third light conversion pattern is disposed to surround the third light-emitting element in the plan view, wherein the second light conversion pattern is constructed to convert the second light emitted from the second light-emitting element into the fourth light, wherein the third light conversion pattern is constructed to convert the third light emitted from the third light-emitting element into the fourth light, wherein the light-receiving element is positioned to receive and sense the fourth light obtained via light conversion of at least one of the second light conversion pattern or the third light conversion pattern.

In an embodiment, the first to third light conversion patterns may include first to third openings overlapping the first to third light-emitting elements, respectively.

In an embodiment, the display device may further comprise a first color filter disposed on the light conversion layer and transmitting the first light; a second color filter disposed on the light conversion layer and transmitting the second light; and a third color filter disposed on the light conversion layer and transmitting the third light , wherein at least a portion of each of the first to third color filters overlaps the light-receiving element.

In an embodiment, the display device may include a first area in which the first light-emitting element and the light-receiving element are disposed; and a second area in which the second light-emitting element and the third light-emitting element are disposed, wherein the first light conversion pattern is disposed in the first area and is absent in the second area.

In an embodiment, the display device may further comprise a first color filter disposed on the light conversion layer and transmitting the first light; a second color filter disposed on the light conversion layer and transmitting the second light; and a third color filter disposed on the light conversion layer and transmitting the third light, wherein in the first area, the first color filter overlaps the first light-emitting element and the light-receiving element, wherein in the second area, the second color filter overlaps the second light-emitting element, and the third color filter overlaps the third light-emitting element.

In an embodiment, each of the first, second, and third light may be visible light, and the fourth light is infrared light.

According to one or more embodiments of the disclosure, an electronic device comprise a display device for displaying an image; a processor configured to provide an image driving signal to the display device; and a power module configured to supply power to the display device and the processor, wherein the display device includes: a substrate; a circuit layer disposed on the substrate; an element layer disposed on the circuit layer, wherein the element layer includes a light-emitting element configured to emit first light having a first wavelength, a light-receiving element positioned to receive and sense second light having a second wavelength, and a pixel defining film patterned to define each of the light-emitting element and the light-receiving element; and a light conversion layer disposed on the element layer and including a light conversion pattern overlapping the pixel defining film, wherein the light conversion pattern converts the first light emitted from the light-emitting element into the second light, wherein the light-receiving element is positioned to receive and sense the second light. Specific features of other embodiments are included in the detailed description and drawings.

According to an embodiment of the present disclosure, the display device having a high resolution and including the light-emitting element and the light-receiving element, and the electronic device including the same may be provided.

The effects according to the embodiments are not limited by those as illustrated above, and other various effects are included in the present disclosure.

### BRIEF DESCRIPTION OF DRAWINGS

The above and other aspects and features of the present disclosure will become more apparent by illustrating in detail embodiments thereof with reference to the attached drawings, in which:

FIG. 1 is a schematic perspective view illustrating an electronic device according to an embodiment;

FIG. 2 is a perspective view illustrating a display device included in an electronic device according to an embodiment;

FIG. 3 is a cross-sectional view illustrating a display device according to an embodiment;

FIG. 4 is a plan view illustrating a light-emitting pixel, a sensing pixel, various drivers, and various lines of a display device according to an embodiment;

FIG. 5 is a block diagram illustrating a light-emitting pixel, a sensing pixel, various drivers, and various lines of a display device according to an embodiment;

FIG. 6 is a circuit diagram illustrating a light-emitting pixel of a display device according to an embodiment;

FIG. 7 is a cross-sectional view illustrating a light-emitting pixel of a display device according to an embodiment;

FIG. 8 is a circuit diagram illustrating a sensing pixel of a display device according to an embodiment;

FIG. 9 is a cross-sectional view illustrating a sensing pixel of a display device according to an embodiment;

FIG. 10 is a plan view illustrating a portion of a display area of a display device according to an embodiment;

FIG. 11 is a cross-sectional view taken along a line X1-X1' of FIG. 10.

FIG. 12 is a cross-sectional view taken along a line X2-X2' of FIG. 10.

FIG. 13 is a cross-sectional view illustrating an operation of a display device according to an embodiment of FIG. 10.

FIG. 14 is a cross-sectional view taken along a line X1-X1' of FIG. 10 in a display device according to another embodiment;

FIG. 15 is a cross-sectional view taken along a line X2-X2' of FIG. 10 in a display device according to still another embodiment;

FIG. 16 is a plan view illustrating a portion of a display area of a display device according to another embodiment;

FIG. 17 is a cross-sectional view taken along a line X3-X3' of FIG. 16;

FIG. 18 is a cross-sectional view illustrating an operation of the display device according to the embodiment of FIG. 16;

FIG. 19 is a block diagram of an electronic device according to an embodiment; and

FIG. 20 is a schematic diagram of an electronic device according to various embodiments.

### DETAILED DESCRIPTIONS

The present inventive concept will now be described more fully herein with reference to the accompanying drawings, in which some embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art.

It is also to be understood that when a layer is referred to as being "on" another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the invention. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, embodiments of the present disclosure will be described in detail with reference to the accompanying drawings.

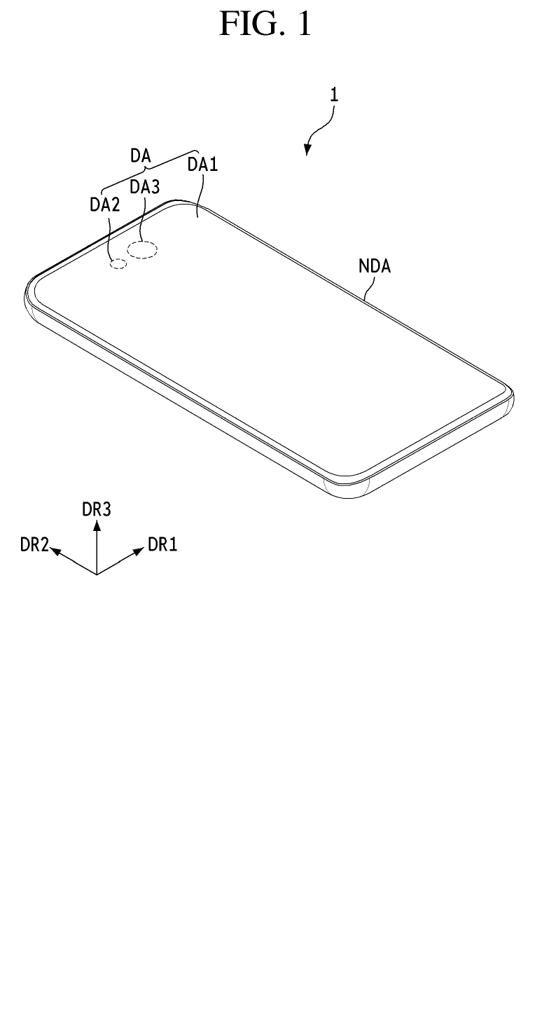

FIG. 1 is a schematic perspective view illustrating an electronic device according to an embodiment.

Referring to FIG. 1, an electronic device 1 displays a moving image or a still image. The electronic device 1 may refer to all electronic devices that provide a display screen. For example, a television, a notebook, a monitor, a billboard, the Internet of Things, a mobile phone, a smart phone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder, and the like that provide a display screen may be the electronic device 1.

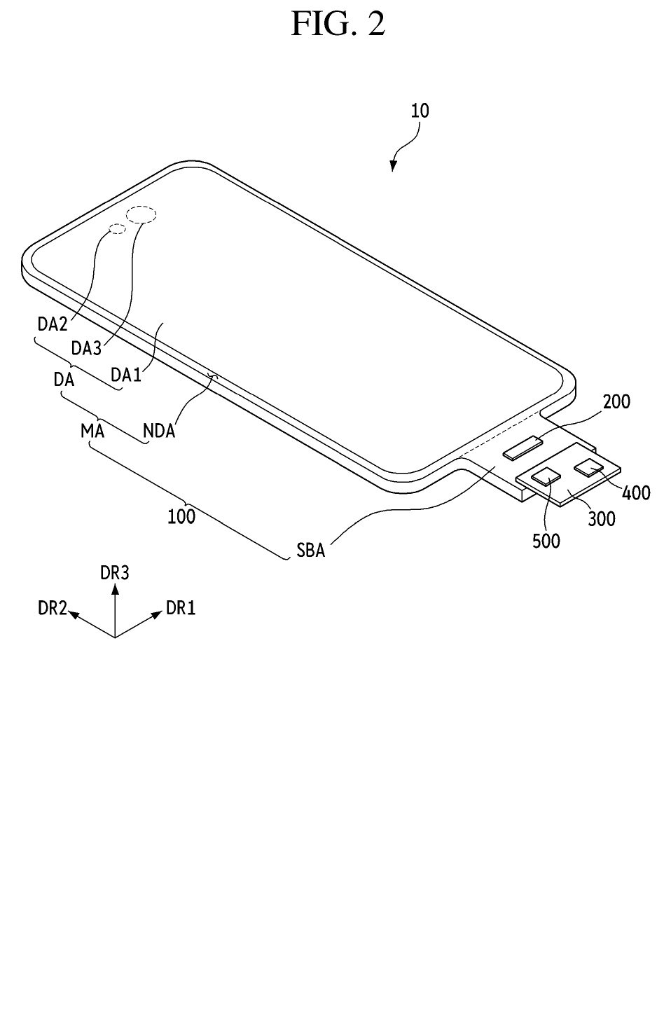

The electronic device 1 may include a display device 10 (see FIG. 2) that provides a display screen. Examples of the display device may include an inorganic light-emitting diode display device, an organic light-emitting display device, a quantum dot light-emitting display device, a plasma display device, a field emission display device, and the like. Hereinafter, as an example of a display device, an organic light-emitting diode display device is applied. However, embodiments of the present disclosure are not limited thereto, and the same technical idea may be applied to other display devices as well.

A shape of the electronic device 1 may be variously modified. For example, the electronic device 1 may have a shape such as a rectangular shape having a long side extending in a column direction, a rectangular shape a long side extending in a row direction, a square shape, a square shape with a rounded corner (vertex), other polygons, a circular shape, or the like. A shape of the display area DA of the electronic device 1 may also be similar to a general shape of the electronic device 1. FIG. 1 illustrates the electronic device 1 having the rectangular shape in which a length in a second direction DR2 is larger than a length in a first direction DR1.

In the illustrated drawing, the first direction DR1 and the second direction DR2 intersect each other and may be referred to as the first and second horizontal directions. For example, the first direction DR1 and the second direction DR2 may be orthogonal to each other. In addition, the third direction DR3 may be a vertical direction intersecting (for example, orthogonal to) the first direction DR1 and the second direction DR2. Unless otherwise defined, herein, a direction indicated by an arrow in each of the first to third directions DR1, DR2, and DR3 may be referred to as one side, and the opposite direction thereto may be referred to as the other side. In addition, "on top of", "upper side", "top", "upper portion" and "upper surface" as used herein mean a direction as indicated by the arrow of the third direction DR3 based on the drawing, while "under", "lower side", "bottom," "lower portion" and "lower surface" mean a direction opposite to the direction as indicated by the arrow of the third direction DR3 based on the drawing.

The electronic device 1 may include a display area DA and a non-display area NDA. The display area DA is an area in which a screen may be displayed, and the non-display area NDA is an area in which a screen is not displayed. The display area DA may be referred to as an active area, and the non-display area NDA may also be referred to as a non-active area. The display area DA may generally occupy an inner area of the electronic device 1.

The display area DA may include a first display area DA1, a second display area DA2, and a third display area DA3. The second display area DA2 and the third display area DA3 are areas in which components for adding various functions to the electronic device 1 are disposed, and the second display area DA2 and the third display area DA3 may correspond to component areas.

For example, a camera module for photographing or recognizing an image, a face recognition sensor module for detecting a face of a user, a pupil recognition sensor module for detecting a pupil of the user, an acceleration sensor module and a geomagnetic sensor module for determining a movement of the display device, a proximity sensor module and an infrared sensor module for detecting proximity to a front surface of the display device 10, an illuminance sensor module for measuring an external brightness level, and the like may be disposed in the second display area DA2 and the third display area DA3.

FIG. 2 is a perspective view illustrating a display device included in an electronic device according to an embodiment.

Referring to FIG. 2 in addition to FIG. 1, the electronic device 1 according to an embodiment may include the display device 10. The display device 10 may provide a screen displayed by the electronic device 1. The display device 10 may have a shape in a plan view similar to that of the electronic device 1. For example, the display device 10 may have a shape similar to a rectangle having a short side extending in the first direction DR1 and a long side extending in the second direction DR2. A corner at which the short side extending in the first direction DR1 and the long side extending in the second direction DR2 meet may be rounded to have a curvature. However, embodiments of the present disclosure are not limited thereto and the corner may be formed at a right angle. The shape in the plan view of the display device 10 is not limited to the rectangle, and may have other polygons, circles, or ellipses.

The display device 10 may include a display panel 100, a display driver 200, a circuit board 300, a touch driver 400, and a power supply 500.

The display panel 100 may include a main area MA and a sub-area SBA.

The main area MA may include a display area DA including pixels for displaying an image, and a non-display area NDA disposed around the display area DA. The display area DA may be disposed in an inner area of the main area MA, and the non-display area NDA may surround the display area DA. The display area DA may include a first display area DA1, a second display area DA2, and a third display area DA3. The display area DA may emit light from a plurality of light-emitting areas or a plurality of opening areas. For example, the display panel 100 may include a pixel circuit including switching elements, a pixel defining film defining the light-emitting area or the opening area, and a self-light-emitting element.

For example, the self-light-emitting element may include at least one of an organic light-emitting diode including an organic light-emitting layer, a quantum dot light-emitting diode including a quantum dot light-emitting layer, an inorganic light-emitting diode including an inorganic semiconductor, and a micro light-emitting diode (Micro LED). However, embodiments of the present disclosure are not limited thereto.

The non-display area NDA may be an area outside of the display area DA. The non-display area NDA may be defined as an edge area of the main area MA of the display panel 100. The non-display area NDA may include a gate driver (not shown) that supplies gate signals to gate lines, and fan-out lines (not shown) that connect the display driver 200 and the display area DA to each other.

The sub-area SBA may be an area extending from one side of the main area MA. The sub-area SBA may include a flexible material capable of bending, folding, rolling, and the like. For example, when the sub-area SBA is bent, the sub-area SBA may overlap the main area MA in a thickness direction (e.g., the third direction DR3). The sub-area SBA may include a pad connected to the display driver 200 and the circuit board 300. In another embodiment, the sub-area SBA may be omitted, and the display driver 200 and the pad may be disposed in the non-display area NDA.

The display driver 200 may output signals and voltages for driving the display panel 100. The display driver 200 may supply data voltages to the data lines. The display driver 200 may supply a power voltage to the power line and may supply a gate control signal to the gate driver. The display driver 200 may be embodied as an Integrated Circuit (IC) and may be mounted on the display panel 100 in a chip on glass (COG) manner, a chip on plastic (COP) manner, or an ultrasonic bonding manner. For example, the display driver 200 may be disposed in the sub-area SBA. When the sub-area is bent, the display driver may overlap the main area MA in the thickness direction. In another example, the display driver 200 may be mounted on the circuit board 300.

The circuit board 300 may be attached onto the pad of the display panel 100 using an anisotropic conductive film (ACF). Lead lines of the circuit board 300 may be electrically connected to the pad of the display panel 100. The circuit board 300 may be embodied as a flexible film such as a flexible printed circuit board, a printed circuit board, or a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and sense a change amount of capacitance between adjacent touch electrodes. For example, the touch driving signal may be a pulse signal having a predetermined frequency. The touch driver 400 may calculate whether an input is made and determine input coordinates based on the amount of change in capacitance between adjacent touch electrodes. The touch driver 400 may be embodied as an integrated circuit (IC).

The power supply 500 may be disposed on the circuit board 300 to supply a power voltage to the display driver 200 and the display panel 100. The power supply 500 may generate a driving voltage and supply the driving voltage to a driving voltage line, and generate a common voltage and supply the common voltage to a common electrode. For example, the driving voltage may be a high potential voltage for driving the light-emitting element, and the common voltage may be a low potential voltage for driving the light-emitting element. The power supply 500 may generate an initialization voltage and supply the initialization voltage to an initialization voltage line, generate a reference voltage and supply the reference voltage to a reference voltage line, generate a bias voltage and supply the bias voltage to a bias voltage line, and generate a reset voltage and supply the reset voltage to a reset voltage line.

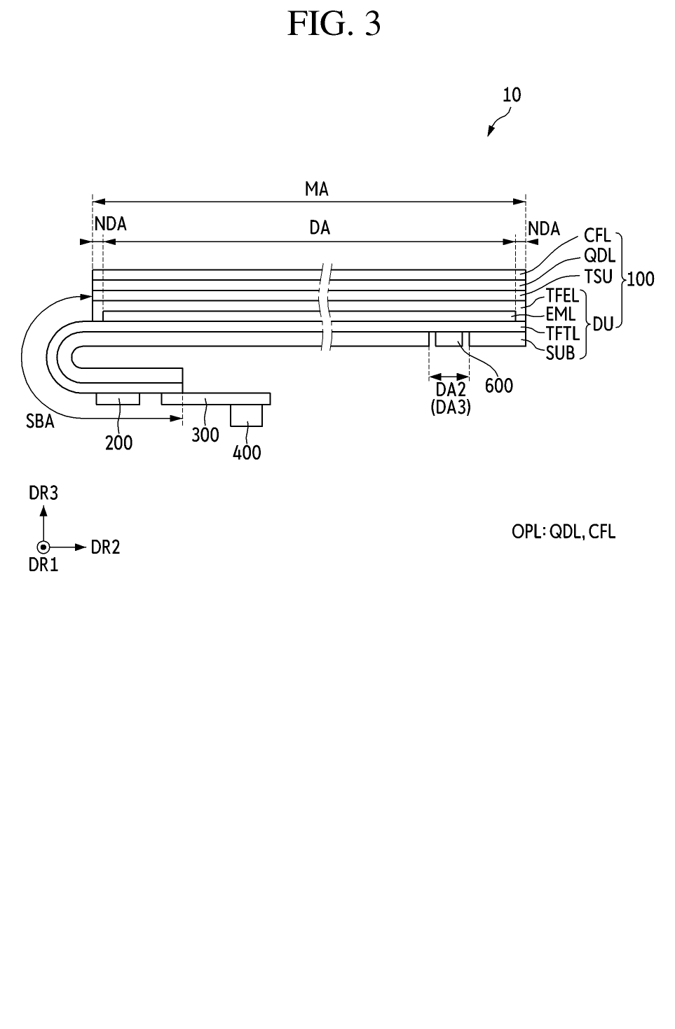

FIG. 3 is a cross-sectional view illustrating a display device according to an embodiment. FIG. 3 illustrates a state in which the sub-area SBA of the display panel 100 is bent in the display device 10 of FIG. 2.

Referring to FIG. 3, the display panel 100 may include a display layer DU, a touch sensing layer TSU, and an optical layer OPL. The display layer DU may include a substrate SUB, a transistor layer TFTL, an element layer EML, and an encapsulation layer TFEL. The optical layer OPL may include a light conversion layer QDL and a color filter layer CFL.

The substrate SUB may be a base substrate or a base member. The substrate SUB may be a flexible substrate capable of bending, folding, rolling, and the like. For example, the substrate SUB may include a polymer resin such as polyimide (PI). However, embodiments of the present disclosure are not limited thereto. In another embodiment, the substrate SUB may include a glass material or a metal material.

The transistor layer TFTL may be disposed on the substrate SUB. The transistor layer TFTL may include a plurality of thin-film transistors constituting the light-emitting pixel and the sensing pixel of the pixels. The transistor layer TFTL may further include gate lines, data lines, power lines, gate control lines, fan-out lines connecting the display driver 200 to the data lines, and lead lines connecting the display driver 200 to the pad. Each of the thin-film transistors TFT may include a semiconductor area, a source electrode, a drain electrode, and a gate electrode. For example, when the gate driver is formed at one side of the non-display area NDA of the display panel 100, the gate driver may include thin-film transistors.

The transistor layer TFTL may be disposed in the display area DA, the non-display area NDA, and the sub-area SBA. The thin-film transistors, the gate lines, the data lines, and the power lines of the transistor layer TFTL may be disposed in the display area DA. The gate control lines and the fan-out lines of the transistor layer TFTL may be disposed in the non-display area NDA. The read lines of the transistor layer TFTL may be disposed in the sub-area SBA.

In the display device 10 according to the present embodiment, the light-emitting pixel circuit for driving the light-emitting element and the sensing pixel circuit for driving the light-receiving element are disposed together in the transistor layer TFTL, thereby realizing the display device 10 which is structurally simple and has a reduced manufacturing cost. For example, the light-emitting pixel circuit and the sensing pixel circuit may share the line layers and the insulating layer included in the transistor layer TFTL with each other, and the line formation process of the light-emitting pixel circuit and the line formation process of the sensing pixel circuit may be performed simultaneously or continuously. That is, the sensing pixel circuit forming process is merely added to the existing manufacturing process of the display device 10, such that the manufacturing cost may be reduced, and some layers may be shared by the light-emitting pixel circuit and the sensing pixel circuit, thereby simplifying the structure.

The element layer EML may be disposed on the transistor layer TFTL. The element layer EML may include the light-emitting element of the light-emitting pixel, the light-receiving element of the sensing pixel, and the pixel defining film defining each of the light-emitting pixel and the sensing pixel. The light-emitting element LD may include a stack formed by sequentially stacking a pixel electrode, a light-emitting layer, and a common electrode, and may emit light. The light-receiving element PD may include a stack formed by sequentially stacking a sensor electrode, a light-receiving layer, and a common electrode and may receive light. The light-emitting elements and the light-receiving elements of the element layer EML may be disposed in the display area DA.

For example, the light-emitting layer may be an organic light-emitting layer including an organic material. The light-emitting layer may include a hole transporting layer, an organic light-emitting layer, and an electron transporting layer. When the pixel electrode receives a predetermined voltage via the transistor of the transistor layer TFTL and the common electrode receives the cathode voltage, holes may migrate to the organic light-emitting layer via the hole transport layer, electrons may migrate to the organic light-emitting layer via the electron transport layer, and the holes and electrons may be combined with each other in the organic light-emitting layer to emit light. For example, the pixel electrode may be an anode electrode, and the common electrode may be a cathode electrode. However, embodiments of the present disclosure are not limited thereto.

In another example, each of the plurality of light-emitting elements may include a quantum dot light-emitting diode including a quantum dot light-emitting layer, an inorganic light-emitting diode including an inorganic semiconductor, or an ultra-micro light-emitting diode.

The light-receiving element may receive light and convert light energy into an electrical signal. When an object is located on the display panel 100, light emitted from the light-emitting element may be reflected from the object, and the light-receiving element may receive the reflected light. Upon receiving the light reflected from the object, the sensing pixel may generate a sensing signal. The main processor may generate sensing data based on the sensing signal, and may determine a shape of the object or a distance from the object based on the sensing data. For example, the light-receiving element may be embodied as an organic photodiode. However, embodiments of the present disclosure are not limited thereto.

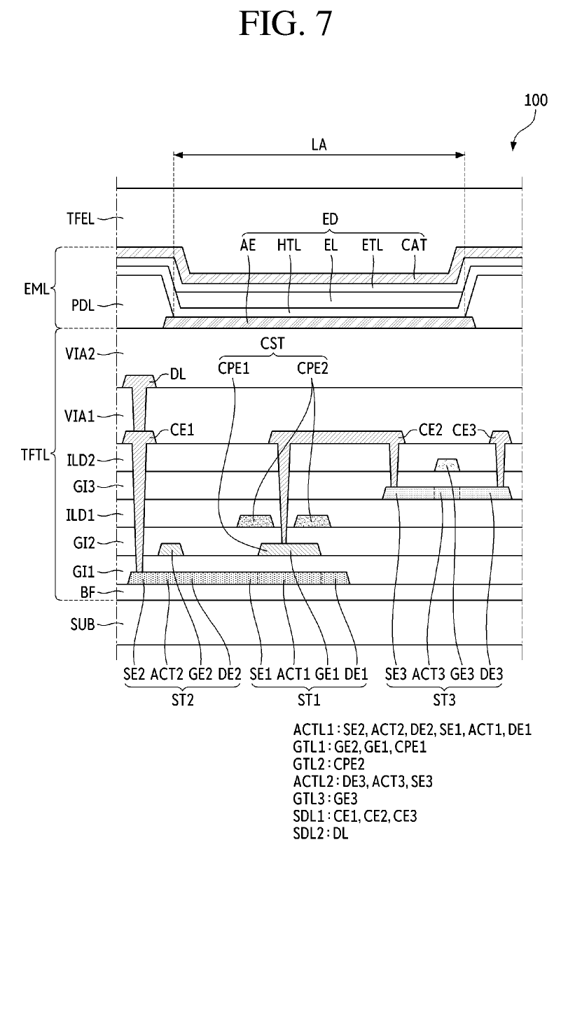

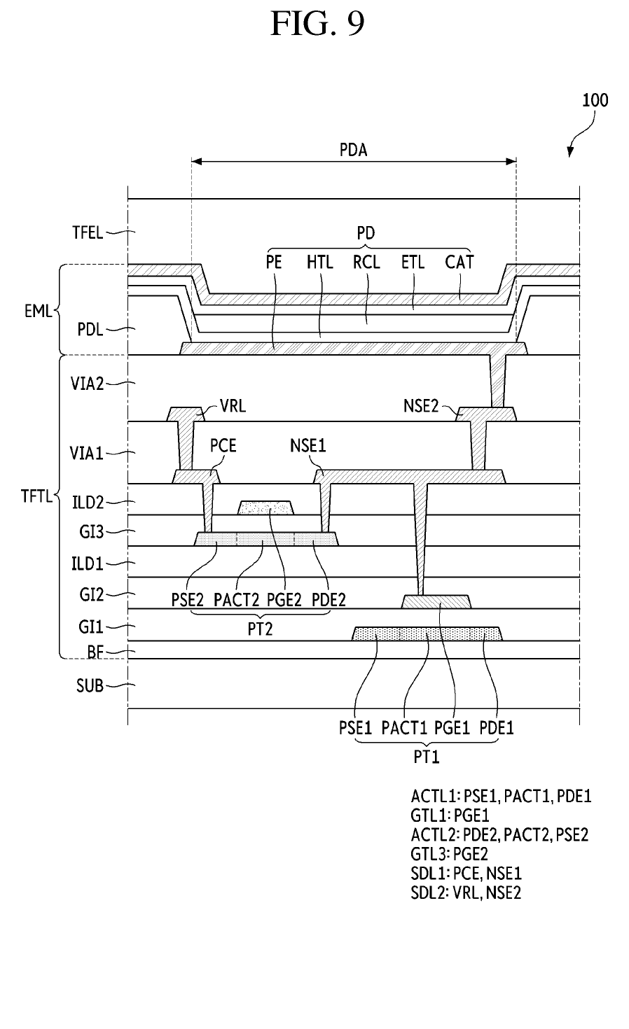

In the display device 10 according to the present embodiment, both the light-emitting element and the light-receiving element are disposed in the element layer EML, thereby realizing the display device 10 that is structurally simple and has a reduced manufacturing cost. For example, a deposition process for forming the light-emitting layer EL (see FIG. 7) of the light-emitting element and a deposition process for forming the light-receiving layer RCL (see FIG. 9) of the light-receiving element may be simultaneously or continuously performed. In addition, the light-emitting element and the light-receiving element may share a hole transport layer HTL (see FIG. 7), an electron transport layer ETL (see FIG. 7), and a common electrode CAT (see FIG. 7) which will be described below with each other. That is, the light-receiving element forming process is merely added to the existing manufacturing process of the display device such that the manufacturing cost may be reduced. Some layers may be shared by the light-emitting element and the light-receiving element, thereby simplifying the structure.

The encapsulation layer TFEL may cover an upper surface and a side surface of the element layer EML and may protect the element layer EML. The encapsulation layer TFEL may include at least one inorganic film and at least one organic film for encapsulating the element layer EML.

The touch sensing layer TSU may be disposed on the encapsulation layer TFEL. The touch sensing layer TSU may include a plurality of touch electrodes for sensing a user's touch in a capacitive manner and touch lines for connecting the plurality of touch electrodes to the touch driver 400. For example, the touch sensing layer TSU may sense a user's touch in a mutual capacitance manner or a self-capacitance manner.

In another embodiment, the touch sensing layer TSU may be disposed on a separate substrate disposed on the display layer DU. In this case, the substrate supporting the touch sensing layer TSU may be a base member encapsulating the display layer DU.

The plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

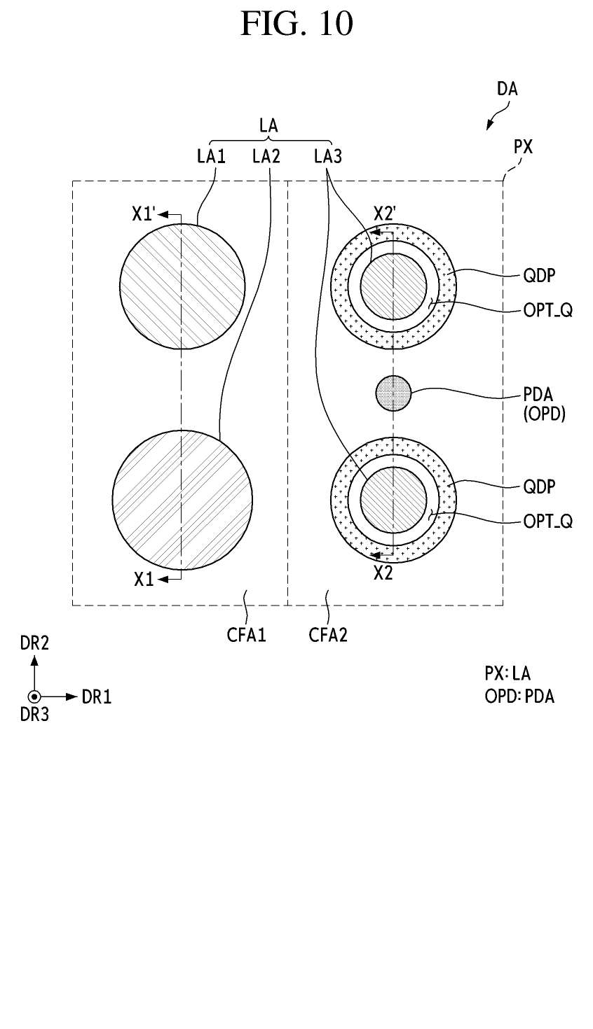

The light conversion layer QDL may be disposed on the touch sensing layer TSU. The light conversion layer QDL may include light conversion patterns QDP (see FIG. 10) disposed in a corresponding manner to specific pixels of the display layer DU. The light conversion layer QDL may convert a wavelength of light incident on the light conversion layer QDL and emit the light of the converted wavelength again. For example, the light conversion layer QDL may convert visible light emitted from the light-emitting element of the display layer DU into infrared light. The display device 10 may include the light conversion layer QDL, and may convert light emitted from the light-emitting element into light that the light-receiving element may sense.

The color filter layer CFL may be disposed on the light conversion layer QDL. The color filter layer CFL may include a plurality of color filters corresponding to the plurality of light-emitting areas. Each of the color filters CF may selectively transmit light of a specific wavelength and block or absorb light of a wavelength other than the specific wavelength. The color filter layer CFL may absorb a portion of light introduced from the outside out of the display device 10 to reduce reflected light caused by external light. Therefore, the color filter layer CFL may prevent the distortion of the color due to the reflection of the external light.

Since the color filter layer CFL is directly disposed on the light conversion layer QDL, the display device 10 may not require a separate substrate for the color filter layer CFL. Accordingly, a thickness of the display device 10 may be relatively small.

In some embodiments, the display device 10 may further include an optical device 600. The optical device 600 may be disposed in the second display area DA2 or the third display area DA3. The optical device 600 may emit or receive light in the infrared, ultraviolet, or visible light band. For example, the optical device 600 may be an optical sensor that senses light incident on the display device 10, such as a proximity sensor, an illuminance sensor, and a camera sensor or an image sensor.

The display device 10 according to the present embodiment includes the light-receiving element embedded in the display panel 100 in addition to the optical device 600 provided separately from the display panel 100 (or instead of the optical device 600), so that the display device 10 may simultaneously perform a light-receiving function as well as a light-emitting function.

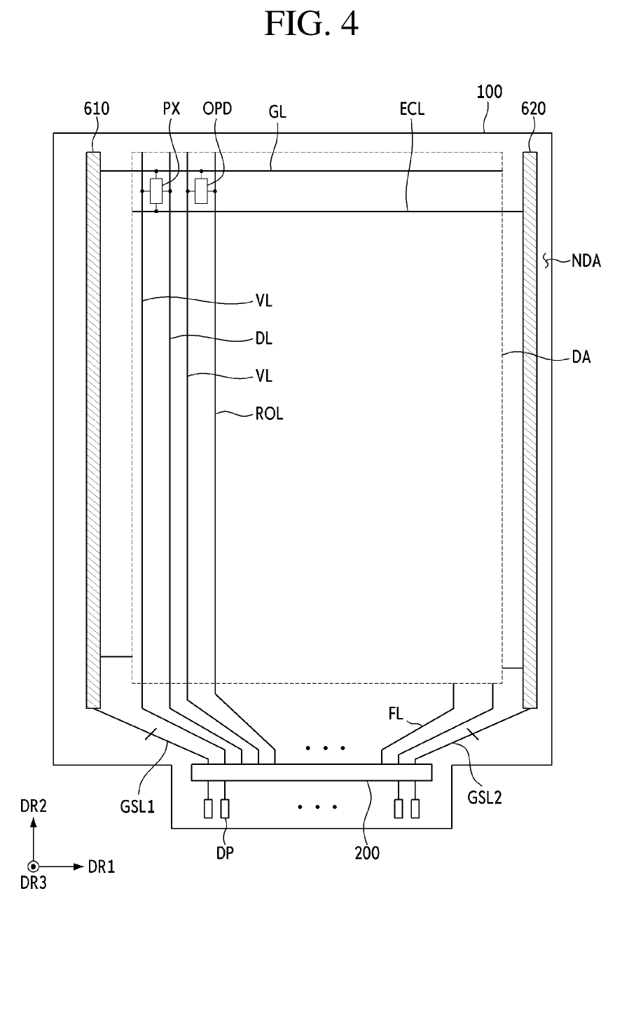

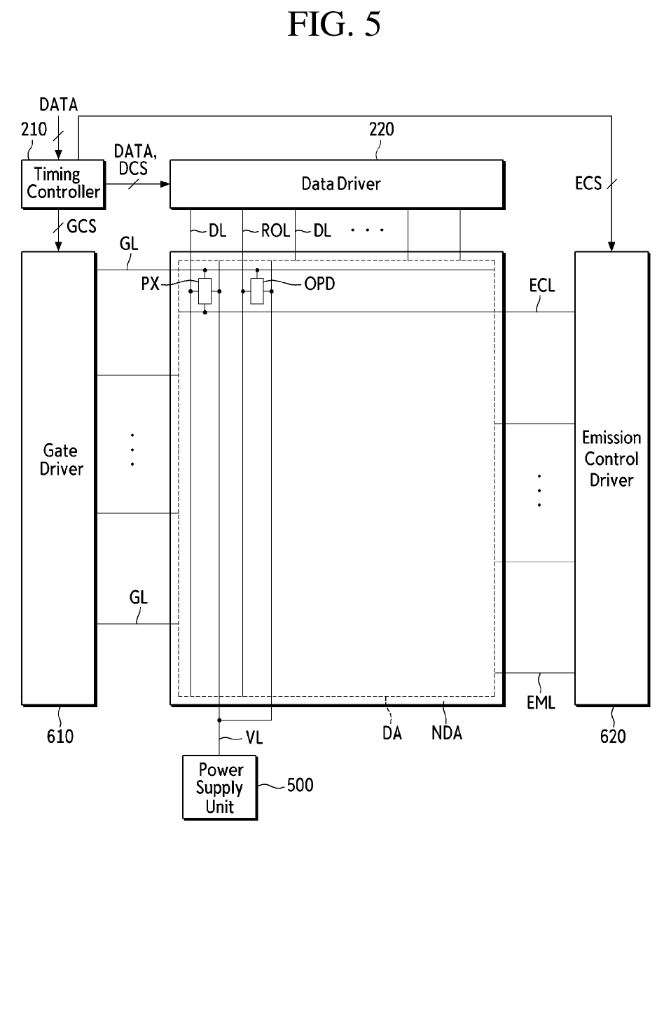

FIG. 4 is a plan view illustrating a light-emitting pixel, a sensing pixel, various drivers, and various lines of a display device according to an embodiment. FIG. 5 is a block diagram illustrating a light-emitting pixel, a sensing pixel, various driving units, and various lines of a display device according to an embodiment.

Referring to FIGS. 4 and 5, the display panel 100 may include a display area DA and the non-display area NDA. The display area DA may include a light-emitting pixel PX, a sensing pixel OPD, a power line VL, a data line DL, a read-out line ROL, a gate line GL, and a light-emission control line ECL.

Each of the plurality of light-emitting pixels PX may be connected to the gate line GL, the light-emission control line ECL, the data line DL, and the power line VL. Each of the plurality of light-emitting pixels PX may include a plurality of transistors, a light-emitting element, and a capacitor.

Each of the plurality of sensing pixels OPD may be connected to the gate line GL, the power line VL, and the read-out line ROL. Each of the plurality of sensing pixels OPD may include a plurality of transistors and a light-receiving element.

The gate lines GL may extend in the first direction DR1 and may be spaced apart from each other in the second direction DR2 intersecting the first direction DR1. The gate lines GL may sequentially supply a gate signal to the light-emitting pixels PX and the sensing pixels OPD.

The light-emission control lines ECL may extend in the first direction DR1 and may be spaced apart from each other in the second direction DR2. The light-emission control lines ECL may sequentially supply emission signals to the light-emitting pixels PX.

The data lines DL may extend in the second direction DR2 and may be spaced apart from each other in the first direction DR1. The data lines DL may supply a data voltage to the light-emitting pixels PX. The data voltage may determine a luminance level of each of the light-emitting pixels PX.

The power line VL may extend in the second direction DR2 and be spaced apart from each other in the first direction DR1. The power line VL may supply a power voltage to the light-emitting pixels PX and the sensing pixels OPD. In this regard, the power voltage may be a driving voltage, a common voltage, an initialization voltage, a reference voltage, a bias voltage, or a reset voltage. The driving voltage may be a high potential voltage for driving the light-emitting pixel PX, and the common voltage may be a low potential voltage for driving the light-emitting pixel PX and the sensing pixel OPD.

The non-display area NDA may surround the display area DA. The non-display area NDA may include a gate driver 610, a light-emission control driver 620, fan-out lines FL, a first gate control line GSL1, and a second gate control line GSL2.

The fan-out lines FL may extend from the display driver 200 to the display area DA. The fan-out lines FL may supply a data voltage received from the display driver 200 to the data line DL, may supply a power voltage received from the display driver 200 to the power line VL, and may supply a sensing signal received from the read-out line ROL to the display driver 200. Accordingly, the display driver 200 may drive the light-emitting pixel PX and the sensing pixel OPD.

The first gate control line GSL1 may extend from the display driver 200 to the gate driver 610. The first gate control line GSL1 may supply the gate control signal GCS received from the display driver 200 to the gate driver 610.

The second gate control line GSL2 may extend from the display driver 200 to the light-emission control driver 620. The second gate control line GSL2 may supply a light-emission control signal ECS received from the display driver 200 to the light-emission control driver 620.

The sub-area SBA may extend from one side of the non-display area NDA. The sub-area SBA may include the display driver 200 and the pad DP. The pad DP may be disposed closer to one edge of the sub-area SBA than the display driver 200 may be. The pad DP may be electrically connected to the circuit board 300 via an anisotropic conductive film (ACF).

The display driver 200 may include a timing controller 210 and a data driver 220.

The timing controller 210 may receive digital video data DATA and timing signals from the circuit board 300. The timing controller 210 may generate a data control signal DCS based on the timing signals, and may control an operation timing of the data driver 220 by supplying the digital video data DATA and the data control signal DCS to the data driver 220. The timing controller 210 may generate a gate control signal GCS and supply the gate control signal GCS to the gate driver 610, and may control an operation timing of the gate driver 610. The timing controller 210 may generate the light-emission control signal ECS and supply the light-emission control signal ECS to the light-emission control driver 620 to control an operation timing of the light-emission control driver 620.

The data driver 220 may convert the digital video data DATA into analog data voltages and supply the analog data voltages to the data lines DL via the fan-out lines FL. The gate signals of the gate driver 610 may select the light-emitting pixels PX to which the data voltage is to be supplied, and the selected light-emitting pixels PX may receive the data voltage via the data lines DL. The data driver 220 may supply the sensing signal received via the read-out line ROL to the main processor.

The power supply 500 may be disposed on the circuit board 300 to supply a power voltage to the display driver 200 and the display panel 100. The power supply 500 may generate a power voltage and supply the power voltage to the power line VL, and may generate a common voltage and supply the common voltage to common electrodes common to the light-emitting pixels PX and the sensing pixels OPD. The power supply 500 may generate the initialization voltage and supply the initialization voltage to the initialization voltage line, generate the reference voltage and supply the reference voltage to the reference voltage line, generate the bias voltage and supply the bias voltage to the bias voltage line, and generate the reset voltage and supply the reset voltage to the reset voltage line.

The gate driver 610 may be disposed outside of the display area DA or at one side of the non-display area NDA, and the light-emission control driver 620 may be disposed outside of the display area DA on a different side than the light-emission control driver 620, or at another side of the non-display area NDA. The embodiment of FIG. 5 depicts the gate driver 610 and the emission control driver 620 as being across the display area DA from each other. However, embodiments of the present disclosure are not limited thereto. For example, the gate driver 610 and the light-emission control driver 620 may be disposed on the same side of the non-display area NDA.

The gate driver 610 may include a plurality of transistors that generate the gate signals based on the gate control signal GCS. The light-emission control driver 620 may include a plurality of transistors that generate the light-emission signals based on the light-emission control signal ECS. For example, the transistors of the gate driver 610 and the transistors of the light-emission control driver 620 may be formed in the same layer as a layer of the transistors of each of the light-emitting pixels PX. The gate driver 610 may supply the gate signals to the gate lines GL, and the light-emission control driver 620 may supply the light emission signals to the light-emission control lines ECL.

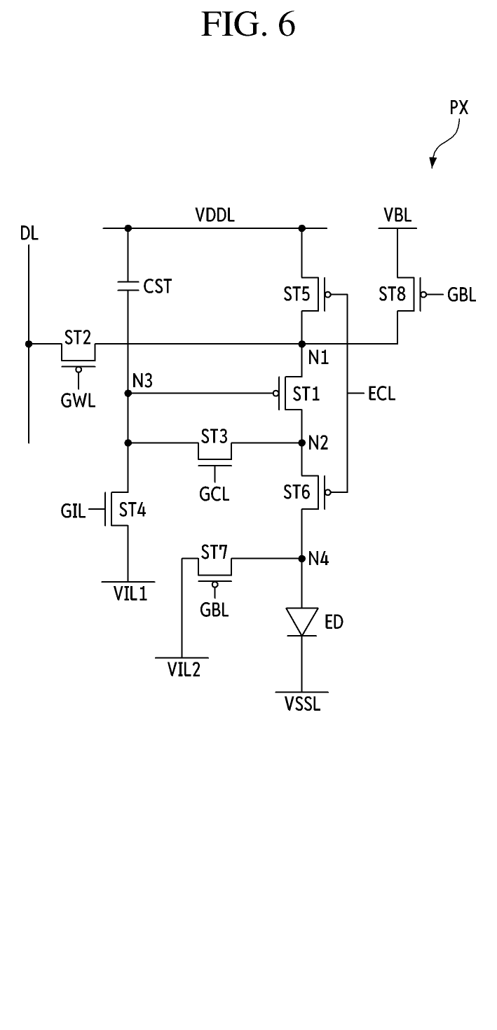

FIG. 6 is a circuit diagram illustrating a light-emitting pixel of a display device according to an embodiment.

Referring to FIG. 6, the light-emitting pixel PX may be connected to a first gate line GWL, a second gate line GCL, a third gate line GIL, a fourth gate line GBL, the light-emission control line ECL, the data line DL, a driving voltage line VDDL, a first initialization voltage line VIL1, a second initialization voltage line VIL2, a bias voltage line VBL, and a low potential line VSSL.

The light-emitting pixel PX may include a light-emitting element ED and a light-emitting pixel circuit for driving the light-emitting element ED. The light-emitting pixel circuit may include first to eighth transistors ST1, ST2, ST3, ST4, ST5, ST6, ST7, and ST8 and a capacitor CST.

The first transistor ST1 may control the driving current supplied to the light-emitting element ED. The first transistor ST1 may include a gate electrode, a first electrode, and a second electrode. The gate electrode of the first transistor ST1 may be connected to a third node N3, the first electrode thereof may be connected to a first node N1, and the second electrode thereof may be connected to a second node N2. For example, the first electrode of the first transistor ST1 may be a source electrode and the second electrode thereof may be a drain electrode. However, embodiments of the present disclosure are not limited thereto.

The first transistor ST1 may control a source-drain current Isd (hereinafter referred to as "driving current") based on the data voltage applied to the gate electrode. The driving current Isd flowing through a channel of the first transistor ST1 may be proportional to a square of a difference between a voltage Vsg between the source electrode and the gate electrode of the first transistor ST1 and a threshold voltage Vth (Isd=k×(Vsg - Vth)²). In this regard, k denotes a proportional coefficient determined by the structure and physical characteristics of the first transistor ST1, Vsg denotes a source-gate voltage of the first transistor ST1, and Vth denotes a threshold voltage of the first transistor ST1.

The light-emitting element ED may receive a driving current to emit light. The light emission amount or luminance of the light-emitting element ED may be proportional to a magnitude of the driving current. The light-emitting element ED may include a first electrode, a second electrode, and a light-emitting layer disposed between the first electrode and the second electrode. The first electrode of the light-emitting element ED may be connected to a fourth node N4. The first electrode of the light-emitting element ED may be connected to a second electrode of the sixth transistor ST6 and a first electrode of the seventh transistor ST7 via the fourth node N4. The second electrode of the light-emitting element ED may be electrically connected to the low potential line VSSL. The second electrode of the light-emitting element ED may receive the low potential voltage from the low potential line VSSL. For example, the first electrode of the light-emitting element ED may be an anode electrode or a pixel electrode, and the second electrode thereof may be a cathode electrode or a common electrode. However, embodiments of the present disclosure are not limited thereto.

The second transistor ST2 may be turned on based on a first gate signal of the first gate line GWL to electrically connect the data line DL to the first node N1 as the first electrode of the first transistor ST1. The second transistor ST2 may be turned on based on the first gate signal to supply the data voltage VDATA to the first node N1. A gate electrode of the second transistor ST2 may be connected to the first gate line GWL, a first electrode thereof may be connected to the data line DL, and a second electrode thereof may be connected to the first node N1. The second electrode of the second transistor ST2 may be connected to the first electrode of the first transistor ST1, a second electrode of the fifth transistor ST5, and a second electrode of the eighth transistor ST8 via the first node N1. For example, the first electrode of the second transistor ST2 may be a source electrode and the second electrode thereof may be a drain electrode. However, embodiments of the present disclosure are not limited thereto.

The third transistor ST3 may be turned on based on a second gate signal of the second gate line GCL to electrically connect the second node N2 as the second electrode of the first transistor ST1 to the third node N3 as the gate electrode of the first transistor ST1. A gate electrode of the third transistor ST3 may be connected to the second gate line GCL, a first electrode thereof may be connected to the second node N2, and a second electrode thereof may be connected to the third node N3. The first electrode of the third transistor ST3 may be connected to the second electrode of the first transistor ST1 and the first electrode of the sixth transistor ST6 via the second node N2. The second electrode of the third transistor ST3 may be connected to the gate electrode of the first transistor ST1, the first electrode of the fourth transistor ST4, and the first capacitor electrode of the capacitor CST via the third node N3. For example, the first electrode of the third transistor ST3 may be a drain electrode and the second electrode thereof may be a source electrode. However, embodiments of the present disclosure are not limited thereto.

The fourth transistor ST4 may be turned on based on a third gate signal of the third gate line GIL to electrically connect the third node N3 as the gate electrode of the first transistor ST1 to the first initialization voltage line VIL1. The fourth transistor ST4 may be turned on based on the third gate signal, thereby discharging the gate electrode of the first transistor ST1 to a first initialization voltage. A gate electrode of the fourth transistor ST4 may be connected to the third gate line GIL, a first electrode thereof may be connected to the third node N3, and a second electrode thereof may be connected to the first initialization voltage line VIL1. The first electrode of the fourth transistor ST4 may be connected to the gate electrode of the first transistor ST1, the second electrode of the third transistor ST3, and a first capacitor electrode of the capacitor CST via the third node N3. For example, the first electrode of the fourth transistor ST4 may be a drain electrode and the second electrode thereof may be a source electrode. However, embodiments of the present disclosure are not limited thereto.

The fifth transistor ST5 may be turned on based on the light-emission signal of the light-emission control line ECL to electrically connect the driving voltage line VDDL to the first node N1 as the first electrode of the first transistor ST1. A gate electrode of the fifth transistor ST5 may be connected to the light-emission control line ECL, a first electrode thereof may be connected to the driving voltage line VDDL, and a second electrode thereof may be connected to the first node N1. The second electrode of the fifth transistor ST5 may be electrically connected to the first electrode of the first transistor ST1, the second electrode of the second transistor ST2, and the second electrode of the eighth transistor ST8 via the first node N1. For example, the first electrode of the fifth transistor ST 5 may be a source electrode and the second electrode thereof may be a drain electrode. However, embodiments of the present disclosure are not limited thereto.

The sixth transistor ST6 may be turned on based on the light-emission signal of the light-emission control line ECL to electrically connect the second node N2 as the second electrode of the first transistor ST1 to the fourth node N4 as the first electrode of the light-emitting element ED. A gate electrode of the sixth transistor ST6 may be connected to the light-emission control line ECL, a first electrode thereof may be connected to the second node N2, and a second electrode thereof may be connected to the fourth node N4. The first electrode of the sixth transistor ST6 may be connected to the second electrode of the first transistor ST1 and the first electrode of the third transistor ST3 via the second node N2. The second electrode of the sixth transistor ST6 may be connected to the first electrode of the light-emitting element ED and the first electrode of the seventh transistor ST7 via the fourth node N4. For example, the first electrode of the sixth transistor ST 6 may be a source electrode and the second electrode thereof may be a drain electrode. However, embodiments of the present disclosure are not limited thereto.

When the fifth transistor ST5, the first transistor ST1, and the sixth transistor ST6 are turned on, the driving current may be supplied to the light-emitting element ED.

The seventh transistor ST7 may be turned on based on a fourth gate signal of the fourth gate line GBL to electrically connect the second initialization voltage line VIL2 to the fourth node N4 as the first electrode of the light-emitting element ED. The seventh transistor ST7 may be turned on based on the fourth gate signal to discharge the first electrode of the light-emitting element ED to a second initialization voltage. A gate electrode of the seventh transistor ST7 may be connected to the fourth gate line GBL, a first electrode thereof may be connected to the fourth node N4, and a second electrode thereof may be connected to the second initialization voltage line VIL2. The first electrode of the seventh transistor ST7 may be connected to the first electrode of the light-emitting element ED and the second electrode of the sixth transistor ST6 via the fourth node N4. For example, the first electrode of the seventh transistor ST7 may be a source electrode and the second electrode thereof may be a drain electrode. However, embodiments of the present disclosure are not limited thereto.

The eighth transistor ST8 may be turned on based on the fourth gate signal of the fourth gate line GBL to electrically connect the bias voltage line VBL to the first node N1 as the first electrode of the first transistor ST1. A gate electrode of the eighth transistor ST8 may be connected to the fourth gate line GBL, a first electrode thereof may be connected to the bias voltage line VBL, and a second electrode thereof may be connected to the first node N1. The second electrode of the eighth transistor ST8 may be electrically connected to the first electrode of the first transistor ST1, the second electrode of the second transistor ST2, and the second electrode of the fifth transistor ST5 via the first node N1. For example, the first electrode of the eighth transistor ST8 may be a source electrode and the second electrode thereof may be a drain electrode. However, embodiments of the present disclosure are not limited thereto. Optionally, the eighth transistor ST8 may be omitted.

Each of the first transistor ST1, the second transistor ST2, the fifth transistor ST5, the sixth transistor ST6, the seventh transistor ST7, and the eighth transistor ST8 may include a silicon-based semiconductor area. For example, each of the first transistor ST1, the second transistor ST2, the fifth transistor ST5, the sixth transistor ST6, the seventh transistor ST7, and the eighth transistor ST8 may include a semiconductor area made of Low Temperature Polycrystalline Silicon (LTPS). The semiconductor area made of low-temperature polycrystalline silicon may have high electron mobility and excellent turn-on characteristics. Accordingly, the display device 10 may include the first transistor ST1, the second transistor ST2, the fifth transistor ST5, the sixth transistor ST6, the seventh transistor ST7, and the eighth transistor ST8 which have excellent turn-on characteristics, thereby stably and efficiently driving the plurality of light-emitting pixels PX.

Each of the first transistor ST1, the second transistor ST2, the fifth transistor ST5, the sixth transistor ST6, the seventh transistor ST7, and the eighth transistor ST8 may be embodied as a p-type transistor. For example, each of the first transistor ST1, the second transistor ST2, the fifth transistor ST5, the sixth transistor ST6, the seventh transistor ST7, and the eighth transistor ST8 may output a current flowing into the first electrode to the second electrode based on a gate low voltage applied to the gate electrode thereof.

Each of the third transistor ST3 and the fourth transistor ST4 may include an oxide-based semiconductor area. For example, each of the third transistor ST3 and the fourth transistor ST4 may have a coplanar structure in which the gate electrode is disposed on an upper portion of the oxide-based semiconductor area. The transistor having the coplanar structure has excellent leakage current characteristics and may operate at a low frequency, thereby reducing power consumption. Accordingly, the display device 10 includes the third transistor ST3 and the fourth transistor ST4 having excellent leakage current characteristics, which means it is able to prevent leakage current from flowing into the light-emitting pixel and stably maintaining the voltage inside the light-emitting pixel.

Each of the third transistor ST3 and the fourth transistor ST4 may be embodied as a n-type transistor. For example, each of the third transistor ST3 and the fourth transistor ST4 may output a current flowing into the first electrode to the second electrode based on a gate high voltage applied to the gate electrode thereof.

The capacitor CST may be disposed between and connected to the third node N3 as the gate electrode of the first transistor ST1 and the driving voltage line VDDL. For example, the first capacitor electrode of the capacitor CST may be connected to the third node N3, and a second capacitor electrode of the capacitor CST may be connected to the driving voltage line VDDL, thereby maintaining a potential difference between the driving voltage line VDDL and the gate electrode of the first transistor ST1.

FIG. 7 is a cross-sectional view illustrating a light-emitting pixel of a display device according to an embodiment.

Referring to FIG. 7 in addition to FIG. 6, the display panel 100 may include the substrate SUB, the transistor layer TFTL, the element layer EML, and the encapsulation layer TFEL. The light-emitting pixel PX may include a light-emitting pixel circuit and a light-emitting element ED. The light-emitting pixel circuit may be disposed in the transistor layer TFTL, and the light-emitting element ED may be disposed in the element layer EML.

The substrate SUB may be a base substrate or a base member. The substrate SUB may be a flexible substrate capable of bending, folding, rolling, and the like. For example, the substrate SUB may include a polymer resin such as polyimide. However, embodiments of the present disclosure are not limited thereto. For another example, the substrate SUB may include a glass material or a metal material.

The transistor layer TFTL includes a buffer layer BF, a first active layer ACTL1, a first gate insulating layer GI1, a first gate layer GTL1, a first gate layer GTL1, a second gate insulating layer GI2, a second gate layer GTL2, a first interlayer insulating layer ILD1, a second active layer ACTL2, a third gate insulating layer GI3, a third gate layer GTL3, a second interlayer insulating layer ILD2, a first source metal layer SDL1, a first via layer VIA1, a second source metal layer SDL2, and a second via layer VIA2.

The buffer layer BF may be disposed on the substrate SUB. For example, the buffer layer BF may include an inorganic film capable of preventing penetration of air or moisture. For example, the buffer layer BF may include a plurality of different inorganic films that are alternately stacked on top of each other.

The first active layer ACTL1 may be disposed on the buffer layer BF. The first active layer ACTL1 may include a silicon-based material. For example, the first active layer ACTL1 may be made of low temperature polycrystalline silicon LTPS. The first active layer ACTL1 may include a semiconductor area ACT1, a first electrode SE1, a second electrode DE of the first transistor ST11, and a semiconductor area ACT2, a first electrode SE2, and a second electrode DE2 of the second transistor ST2.

The first gate insulating layer GI1 may be disposed on the first active layer ACTL1. The first gate insulating layer GI1 may insulate the first active layer ACTL1 and the first gate layer GTL1.

The first gate layer GTL1 may be disposed on the first gate insulating layer GI1. The first gate layer GTL1 may include a gate electrode GE1 of the first transistor ST1, a gate electrode GE2 of the second transistor ST2, and a first capacitor electrode CPE1. The gate electrode GE1 of the first transistor ST1 may be a portion of the first capacitor electrode CPE1, and the gate electrode GE2 of the second transistor ST2 may be a portion of the first gate line GWL.

The second gate insulating layer GI2 may be disposed on the first gate layer GTL1. The second gate insulating layer GI2 may insulate the first gate layer GTL1 and the second gate layer GTL2.

The second gate layer GTL2 may be disposed on the second gate insulating layer GI2. The second gate layer GTL2 may include a second capacitor electrode CPE2. The second capacitor electrode CPE2 may overlap the first capacitor electrode CPE 1.

The first interlayer insulating layer ILD1 may be disposed on the second gate layer GTL2. The first interlayer insulating layer ILD1 may insulate the second gate layer GTL2 and the second active layer ACTL2.

The second active layer ACTL2 may be disposed on the first interlayer insulating layer ILD1. The second active layer ACTL2 may include an oxide-based material. The second active layer ACTL2 may include a semiconductor area ACT3, a first electrode DE3, and a second electrode SE3 of the third transistor ST3.

The third gate insulating layer GI3 may be disposed on the second active layer ACTL2. The third gate insulating layer GI3 may insulate the second active layer ACTL2 and the third gate layer GTL3.

The third gate layer GTL3 may be disposed on the third gate insulating layer GI3. The third gate layer GTL3 may include the gate electrode GE3 of the third transistor ST3. The gate electrode GE3 of the third transistor ST3 may be a portion of the second gate line GCL.

The second interlayer insulating layer ILD2 may be disposed on the third gate layer GTL3. The second interlayer insulating layer ILD2 may insulate the third gate layer GTL 3 and the first source metal layer SDL1.

The first source metal layer SDL1 may be disposed on the second interlayer insulating layer ILD2. The first source metal layer SDL1 may include first to third connection electrodes CE1, CE2, and CE3. The first connection electrode CE1 may electrically connect the data line DL and the first electrode SE2 of the second transistor ST2 to each other. The second connection electrode CE2 may electrically connect the first capacitor electrode CPE1 and the second electrode SE3 of the third transistor ST3 to each other. The third connection electrode CE3 may electrically connect the first electrode DE3 of the third transistor ST3 and the second electrode DE1 of the first transistor ST1 to each other.

The first via layer VIA1 may be disposed on the first source metal layer SDL1. The first via layer VIA1 may insulate the first source metal layer SDL1 and the second source metal layer SDL2 from each other. An upper surface of the first via layer VIA1 may be flat. The first via layer VIA1 may include an organic insulating material such as polyimide.

The second source metal layer SDL2 may be disposed on the first via layer VIA1. The second source metal layer SDL2 may include the data line DL.

The second via layer VIA2 may be disposed on the second source metal layer SDL2. The second via layer VIA2 may insulate the second source metal layer SDL2 and the pixel electrode AE from each other. An upper surface of the second via layer VIA2 may be flat. The second via layer VIA2 may include an organic insulating material such as polyimide.

The element layer EML may include the pixel defining film PDL and the light-emitting element ED.

The pixel defining film PDL may be disposed on the second via layer VIA2. The pixel defining film PDL may define each of the plurality of light-emitting areas LA. The pixel defining film PDL may include an organic insulating material such as polyimide. However, embodiments of the present disclosure are not limited thereto.

The light-emitting element ED may include the pixel electrode AE, the hole transport layer HTL, the light-emitting layer EL, the electron transport layer ETL, and the common electrode CAT. The pixel electrode AE may be disposed on the second via layer VIA2. The pixel electrode AE may overlap each of the plurality of light-emitting areas LA defined by the pixel defining film PDL. The pixel electrode AE may receive a driving current from the pixel circuit of the light-emitting pixel PX.

The hole transport layer HTL may be disposed on the pixel electrode AE in the light-emitting area LA, and may be disposed on the pixel defining film PDL in an area other than the light-emitting area LA. The hole transport layer HTL is not separated between light-emitting pixels PX, and may be implemented as a continuous common layer extending across the light-emitting pixels PX and the sensing pixels OPD.

The light-emitting layer EL may be disposed on the hole transport layer HTL in the light-emitting area LA. For example, the light-emitting layer EL may be an organic light-emitting layer made of an organic material. However, embodiments of the present disclosure are not limited thereto.

The electron transport layer ETL may be disposed on the light-emitting layer EL in the light-emitting area LA, and may be disposed on the hole transport layer HTL in an area other than the light-emitting area LA. The electron transport layer ETL is not separate for each light-emitting pixel PX, and may be implemented as a continuous common layer extending across the light-emitting pixels PX and the sensing pixels OPD.

The common electrode CAT may be disposed on the electron transport layer ETL. Unlike the pixel electrode AE, the common electrode CAT is not separated between each light-emitting pixel PX, and may be implemented as a continuous layer extending across the light-emitting pixels PX and the sensing pixels OPD. The common electrode CAT may be a transparent electrode and may transmit light. The common electrode CAT may be electrically connected to the low potential line VSSL, and may receive a low potential voltage, a common voltage, or a cathode voltage.

In one example, the light-emitting layer EL is embodied as an organic light-emitting layer. In this case, when a pixel circuit of the light-emitting pixel PX applies a predetermined voltage to the pixel electrode AE and the common electrode CAT receives the common voltage or the cathode voltage, holes may migrate to the light-emitting layer EL through the hole transport layer HTL, electrons may migrate to the light-emitting layer EL through the electron transport layer ETL, and the holes and the electrons may be combined with each other in the light-emitting layer EL to emit light.

The encapsulation layer TFEL may be disposed on the common electrode CAT to cover the plurality of light-emitting elements ED. The encapsulation layer TFEL may include at least one inorganic film to prevent oxygen or moisture from penetrating into the plurality of light-emitting elements ED. The encapsulation layer TFEL may include at least one organic film to protect the plurality of light-emitting elements ED from foreign substances such as dust.

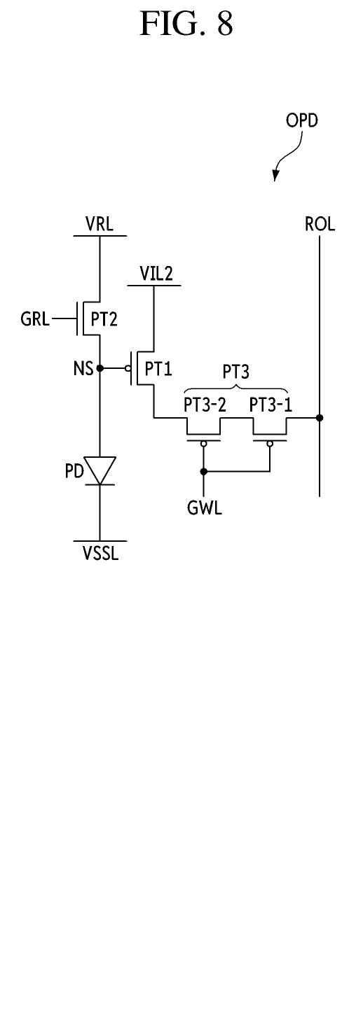

FIG. 8 is a circuit diagram illustrating a sensing pixel of a display device according to an embodiment.

Referring to FIG. 8, the sensing pixel OPD may be connected to the first gate line GWL, the reset signal line GRL, the reset voltage line VRL, the second initialization voltage line VIL2, the low potential line VSSL, and the read-out line ROL.

The sensing pixel OPD may include the light-receiving element PD and a sensing pixel circuit that drives the light-receiving element PD. The sensing pixel circuit may include first to third sensor transistors PT1, PT2, and PT3.

The first sensor transistor PT1 may include a gate electrode, a first electrode, and a second electrode. The gate electrode of the first sensor transistor PT1 may be connected to a sensor node NS, the first electrode thereof may be connected to the third sensor transistor PT3, and the second electrode thereof may be connected to the second initialization voltage line VIL2. The first sensor transistor PT1 may control a source-drain current Isd (hereinafter referred to as a "sensing current") based on a voltage of the sensor node NS as the first electrode of the light-receiving element PD. The sensing current Isd flowing through a channel of the first sensor transistor PT1 may be proportional to a square of a difference between a voltage Vsg between the source electrode and the gate electrode of the first sensor transistor PT1 and a threshold voltage Vth thereof (Isd=k' × (Vsg - Vth)²). In this regard, k' is a proportional coefficient determined by the structure and physical characteristics of the first sensor transistor PT1, Vsg is a source-gate voltage of the first sensor transistor PT1, and Vth is a threshold voltage of the first sensor transistor PT1. The first electrode of the first sensor transistor PT1 may be a source electrode and the second electrode thereof may be a drain electrode. However, embodiments of the present disclosure are not limited thereto.

The second sensor transistor PT2 may be turned on based on a reset signal of the reset signal line GRL to discharge the voltage of the sensor node NS to the reset voltage. A gate electrode of the second sensor transistor PT2 may be connected to the reset signal line GRL, a first electrode thereof may be connected to the sensor node NS, and a second electrode thereof may be connected to the reset voltage line VRL. The first electrode of the second sensor transistor PT2 may be connected to the first electrode of the light-receiving element PD and the gate electrode of the first sensor transistor PT1 via the sensor node NS. The first electrode of the second sensor transistor PT2 may be a drain electrode and the second electrode thereof may be a source electrode. However, embodiments of the present disclosure are not limited thereto.

The third sensor transistor PT3 may be turned on based on a first gate signal of the first sensor transistor PT1 to electrically connect the first electrode of the first sensor transistor PT1 to the read-out line ROL. The third sensor transistor PT3 may include a (3-1)th sensor transistor PT3-1 and a (3-2)th sensor transistor PT3-2 connected in series with each other. The (3-1)th sensor transistor PT3-1 and the (3-2)th sensor transistor PT3-2 may be connected in series with and disposed between the first electrode of the first sensor transistor PT1 and the read-out line ROL. A gate electrode of the (3-1)th sensor transistor PT3-1 and a gate electrode of the (3-2)th sensor transistor PT3-2 may be integrally formed with each other to be electrically connected to the first gate line GWL. A first electrode of the (3-1)th sensor transistor PT3-1 may be connected to the read-out line ROL, and a second electrode of the (3-2)th sensor transistor PT3-2 may be connected to the first electrode of the first sensor transistor PT1. A second electrode of the (3-1)th sensor transistor PT3-1 and a first electrode of the (3-2)th sensor transistor PT3-2 may be integrally formed with each other. The first electrode of each of the (3-1)th sensor transistor PT3-1 and the (3-2)th sensor transistor PT3-2 may be a source electrode and the second electrode thereof may be a drain electrode. However, embodiments of the present disclosure are not limited thereto.

The light-receiving element PD may receive light and convert light energy into an electrical signal. The first electrode of the light-receiving element PD may be connected to the sensor node NS as the gate electrode of the first sensor transistor PT1, and the second electrode thereof may be connected to the low potential line VSSL. The second electrode of the light-receiving element PD may receive a low potential voltage from the low potential line VSSL. For example, the first electrode of the light-receiving element PD may be a sensor electrode and the second electrode thereof may be a common electrode. However, embodiments of the present disclosure are not limited thereto.

When an object is positioned on the display panel 100, light emitted from the light-emitting element may be reflected from the object, and the light-receiving element PD may receive the reflected light. The light-receiving element PD may convert the energy of light into an electrical signal (current or voltage) generated between the first electrode and the second electrode, and the converted electrical signal may flow from the low potential line VSSL to the sensor node NS as a reverse bias current. For example, when the light-receiving element PD receives light such that an electric field is generated between the first electrode and the second electrode of the light-receiving element PD, a current may flow through the light-receiving element PD in a proportional manner to the amount of light, and a voltage of the sensor node NS may increase. Accordingly, when the light-receiving element PD receives light, the voltage of the sensor node NS may increase, and a magnitude of the sensing current (or source-drain current) of the first sensor transistor PT1 may decrease. The sensing current of the first sensor transistor PT1 as the sensing signal may be applied to the display driver 200 via the third sensor transistor PT3 and the read-out line ROL.

FIG. 9 is a cross-sectional view illustrating a sensing pixel of a display device according to an embodiment.

Referring to FIG. 9 in addition to FIG. 8, the display panel 100 may include the substrate SUB, the transistor layer TFTL, the element layer EML, and the encapsulation layer TFEL. The sensing pixel OPD may include the sensing pixel circuit and the light-receiving element PD. The sensing pixel circuit may be disposed in the transistor layer TFTL, and the light-receiving element PD may be disposed in the element layer EML.

The description of the substrate SUB and the encapsulation layer TFEL has been set forth above with reference to FIG. 7, and thus will be omitted.

The transistor layer TFTL may include the buffer layer BF, the first active layer ACTL1, the first gate insulating layer GI1, the first gate layer GTL1, the second gate insulating layer GI2, the first interlayer insulating layer ILD1, the second active layer ACTL2, the third gate insulating layer GI3, the third gate layer GTL3, the second interlayer insulating layer ILD2, the first source metal layer SDL1, the first via layer VIA1, the second source metal layer SDL2, and the second via layer VIA2.

The description of the buffer layer BF, the first gate insulating layer GI1, the second gate insulating layer GI2, the first interlayer insulating layer ILD1, the third gate insulating layer GI3, the second interlayer insulating layer ILD2, the first via layer VIA1, and the second via layer VIA2 of the transistor layer TFTL has been set forth above with reference to FIG. 7, and thus will be omitted.

The first active layer ACTL1 may be disposed on the buffer layer BF. The first active layer ACTL1 may include a silicon-based material. For example, the first active layer ACTL1 may be made of low temperature polycrystalline silicon LTPS. The first active layer ACTL1 may include a semiconductor area PACT1, a first electrode PSE1, and a second electrode PDE1 of the first sensor transistor PT1.

The first gate layer GTL1 may be disposed on the first gate insulating layer GI1. The first gate layer GTL1 may include the gate electrode PGE1 of the first sensor transistor PT1.

The second active layer ACTL2 may be disposed on the first interlayer insulating layer ILD1. The second active layer ACTL2 may include an oxide-based material. The second active layer ACTL2 may include a semiconductor area PACT2, a first electrode PDE2, and a second electrode PSE2 of the second sensor transistor PT2.

The third gate layer GTL3 may be disposed on the third gate insulating layer GI3. The third gate layer GTL3 may include the gate electrode PGE2 of the second sensor transistor PT2. The gate electrode PGE2 of the second sensor transistor PT2 may be a portion of the reset signal line GRL.

The first source metal layer SDL1 may be disposed on the second interlayer insulating layer ILD2. The first source metal layer SDL1 may include a sensor connection electrode PCE and a first sensor node electrode NSE1. The sensor connection electrode PCE may electrically connect the reset voltage line VRL and the second electrode PSE2 of the second sensor transistor PT2 to each other. The first sensor node electrode NSE1 may electrically connect the first electrode PDE2 of the second sensor transistor PT2 and the gate electrode PGE1 of the first sensor transistor PT1 to each other.

The second source metal layer SDL2 may be disposed on the first via layer VIA1. The second source metal layer SDL2 may include the reset voltage line VRL and a second sensor node electrode NSE2. The second sensor node electrode NSE2 may electrically connect the sensor electrode PE and the first sensor node electrode NSE1 to each other.

The light-receiving element PD may include a sensor electrode PE, the hole transport layer HTL, a light-receiving layer RCL, the electron transport layer ETL, and the common electrode CAT. The sensor electrode PE may be disposed on the second via layer VIA2, and may be disposed in the same layer as that of the pixel electrode AE of the light-emitting element ED. Each sensor electrode PE may overlap each of the plurality of sensing areas PDA defined by the pixel defining film PDL.

The hole transport layer HTL may be disposed on the sensor electrode PE in the sensing area PDA, and may be disposed on the pixel defining film PDL in an area other than the sensing area PDA. The hole transport layer HTL is not separate for each sensing pixel OPD, and may be implemented as a continuous common layer extending across the light-emitting pixels PX and the sensing pixels OPD.

The light-receiving layer RCL may be disposed on the hole transport layer HTL. The light-receiving layer RCL may receive light emitted from the light-emitting area LA and then reflected from the object. Light emitted from the light-emitting element ED of the light-emitting area LA may be reflected from the object, and the reflected light may reach the light-receiving layer RCL. The light-receiving element PD may convert the energy of the light into an electrical signal (current or voltage) generated between the sensor electrode PE and the common electrode CAT, and the converted electrical signal may flow to the sensor node NS of FIG. 8 as a reverse bias current. For example, when the light-receiving element PD receives light such that the electric field is generated between the sensor electrode PE of the light-receiving element PD and the common electrode CAT, a current may flow through the light-receiving element PD in a proportional manner to the amount of light.

The electron transport layer ETL may be disposed on the light-receiving layer RCL in the sensing area PDA and may be disposed on the hole transport layer HTL in an area other than the sensing area PDA. The electron transport layer ETL is not separated between sensing pixels OPD, and may be a continuous layer extending across the light-emitting pixels PX and sensing pixels OPD.

The common electrode CAT may be disposed on the electron transport layer ETL. For example, the common electrode CAT may not be separated between sensing pixels, and may be a continuous layer of electrode extending across the light-emitting pixels PX and the sensing pixels OPD. The common electrode CAT may be a transparent electrode and may transmit light. The common electrode CAT may be electrically connected to the low potential line VSSL and may receive a low potential voltage, a common voltage, or a cathode voltage.

FIG. 10 is a plan view illustrating a portion of a display area of a display device according to an embodiment.

Referring to FIG. 10, the display device 10 may include a plurality of light-emitting pixels PX. Although one light-emitting pixel PX is illustrated in the drawings, the light-emitting pixels PX of FIG. 10 may be repeatedly arranged in the display area DA.

The light-emitting pixel PX may include a plurality of light-emitting areas LA. For example, one light-emitting pixel PX may include one first light-emitting area LA1, one second light-emitting area LA2, and two third light-emitting areas LA3. However, embodiments of the present disclosure are not limited thereto. The number of light-emitting areas LA disposed in the light-emitting pixel PX may be variously changed.

The light-emitting pixel PX may include at least one light-emitting element ED. In some embodiments, the light-emitting elements ED included in the light-emitting pixel PX may emit light beams of the same or different colors. For example, the light-emitting element ED disposed in the first light-emitting area LA1 may emit red light as first light, the light-emitting element ED disposed in the second light-emitting area LA2 may emit green light as second light, and the light-emitting element ED disposed in the third light-emitting area LA3 may emit blue light as third light. However, embodiments of the present disclosure are not limited thereto.

The light-emitting areas LA may emit light beams of various colors. For example, the first light-emitting area LA1 may emit light of red as a first color, the second light-emitting area LA2 may emit light of green as a second color, and the third light-emitting area LA3 may emit light of blue as a third color. However, embodiments of the present disclosure are not limited thereto.

In an embodiment, each of the light-emitting areas LA of the display device 10 may be an area in which the light-emitting layer EL overlaps the pixel electrode AE. For example, each of the light-emitting areas LA may be defined in a corresponding manner to each of a plurality of openings defined in the pixel defining film PDL.

The plurality of light-emitting areas LA may be spaced apart from each other in each of the first direction DR1 and the second direction DR2. For example, the first light-emitting area LA1 may be spaced apart from the third light-emitting area LA3 in the first direction DR1 and spaced apart from the second light-emitting area LA2 in the second direction DR2. The second light-emitting area LA2 may be spaced apart from the third light-emitting area LA3 in the first direction DR1, and may be spaced apart from the first light-emitting area LA1 in the second direction DR2. One of the two third light-emitting areas LA3 may spaced apart from the first light-emitting area LA1 in the first direction DR1, and the other of the two third light-emitting areas LA3 may be spaced apart from the second light-emitting area LA2 in the first direction DR1. The two third light-emitting areas LA3 may be spaced apart from each other in the second direction DR2. However, embodiments of the present disclosure are not limited thereto, and the arrangement of the light-emitting areas LA in the light-emitting pixel PX may be variously modified.

In an embodiment, sizes of the light-emitting areas LA may be different from each other. For example, the size of the third light-emitting area LA3 may be smaller than the size of each of the first light-emitting area LA1 and the second light-emitting area LA2, and the size of the first light-emitting area LA1 may be smaller than the size of the second light-emitting area LA2. The intensity of light emitted from each light-emitting area LA may vary based on the size of each light-emitting area LA. A color of a screen displayed on the display device 10 or the electronic device 1 may be controlled by adjusting the size of each light-emitting area LA. FIG. 10 illustrates that the size of the third light-emitting area LA3 is the smallest. However, embodiments of the present disclosure are not limited thereto. The size of each light-emitting area LA may be freely adjusted based on the target color of the screen in the display device 10 and the electronic device 1. In addition, the size of each light-emitting area LA may be related to light efficiency, the lifespan of the light-emitting element ED, etc., and may be in a trade-off relationship with reflection of external light. The size of each light-emitting area LA may be adjusted in consideration of the above factors.

The display device 10 may include a plurality of sensing pixels OPD. Although one sensing pixel OPD is illustrated in the drawings, the sensing pixels OPD of FIG. 10 may be repeatedly arranged in the display area DA. The sensing pixel OPD may overlap the light-emitting pixel PX in the third direction DR3. For example, the sensing pixel OPD may be disposed in the light-emitting pixel PX in a plan view.

In the display device 10 according to the present embodiment, the sensing pixel OPD is disposed in (or so as to overlap) the light-emitting pixel PX, so that a separate area in which the sensing pixel OPD is disposed does not need to be provided, and thus the high resolution display device 10 may be implemented.

The sensing pixel OPD may include at least one sensing area PDA. The sensing area PDA may receive light emitted from the light-emitting area LA and then reflected from the object. One sensing area PDA may include at least one light-receiving element PD. In some embodiments, the light-receiving element PD may receive light of infrared wavelength.

In an embodiment, the sensing area PDA of the display device 10 may be an area in which the light-receiving layer RCL overlaps the sensor electrode PE. For example, the sensing area PDA may be defined in a corresponding manner to each of a plurality of openings defined in the pixel defining film PDL.

The sensing area PDA may be surrounded with the light-emitting areas LA. The sensing area PDA may be arranged with and spaced apart from the light-emitting areas LA in the first direction DR1 and the second direction DR2. For example, the sensing area PDA may be disposed between the third light-emitting areas LA3 in the second direction DR2.

The size of the sensing area PDA may be different from the size of the light-emitting area LA. For example, the size of the sensing area PDA may be smaller than the size of the light-emitting area LA. The light-emitting area LA may be larger to improve the light emission, and the sensing area PDA may be smaller and more densely arranged to improve sensing accuracy. However, embodiments of the present disclosure are not limited thereto.

In the drawings, it is illustrated that one sensing area PDA is disposed between four light-emitting areas LA. However, embodiments of the present disclosure are not limited thereto. A larger number of sensing areas PDA may be disposed between the light-emitting areas LA.

In the drawings, each of the light-emitting areas LA and the sensing areas PDA is illustrated as having a circular shape in a plan view. However, embodiments of the present disclosure are not limited thereto. The shape in the plan view of each of the light-emitting areas LA and the sensing areas PDA may be variously modified, such as a polygonal shape or an elliptical shape.

The display device 10 according to the present embodiment may include the light conversion pattern QDP disposed around the light-emitting area LA and the sensing area PDA. For example, the light conversion patterns QDP may be disposed to surround the third light-emitting area LA3 in a plan view, and the light conversion patterns QDP may be respectively located at opposite sides in the second direction DR2 while the sensing area PDA is disposed therebetween in the second direction DR2.

The light conversion pattern QDP may convert a wavelength of light emitted from the light-emitting area LA. For example, the light conversion pattern QDP may convert the visible light of the blue wavelength emitted from the third light-emitting area LA3 into infrared light. The light of the infrared wavelength obtained via the light conversion of the light conversion pattern QDP may be sensed by the light-receiving element PD of the sensing area PDA.

In some embodiments, the light conversion pattern QDP may have a donut or ring shape. For example, the light conversion pattern QDP may include an opening OPT_Q defined approximately in a center of the light conversion pattern QDP. The size of the opening OPT_Q may be greater than that of the third light-emitting area LA3 in plan view. That is, an inner side surface of the light conversion pattern QDP may be located outside of an outer circumference of the third light-emitting area LA3.

As illustrated in FIG. 10, the light-emitting pixel PX of the display area DA may include a first area CFA1 and a second area CFA2. The first area CFA1 may be an area in which the first light-emitting area LA1 and the second light-emitting area LA2 are disposed, and the second area CFA2 may be an area in which the third light-emitting area LA3 and the sensing area PDA are disposed. In some embodiments, the light conversion pattern QDP may not be disposed in the first area CFA1, and the light conversion pattern QDP may be disposed in the second area CFA2.

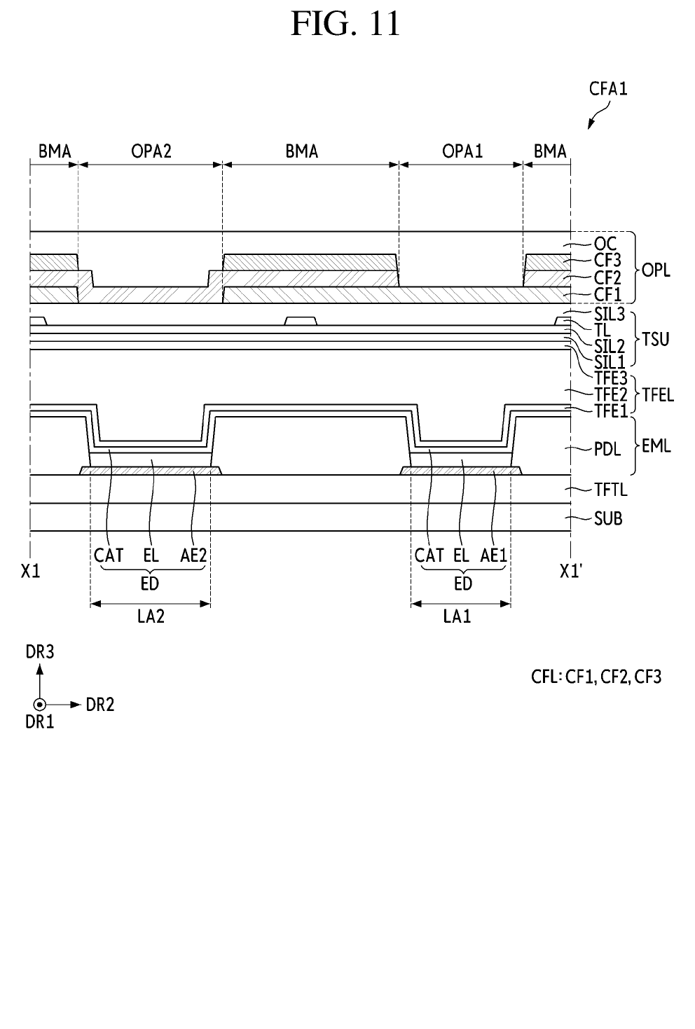

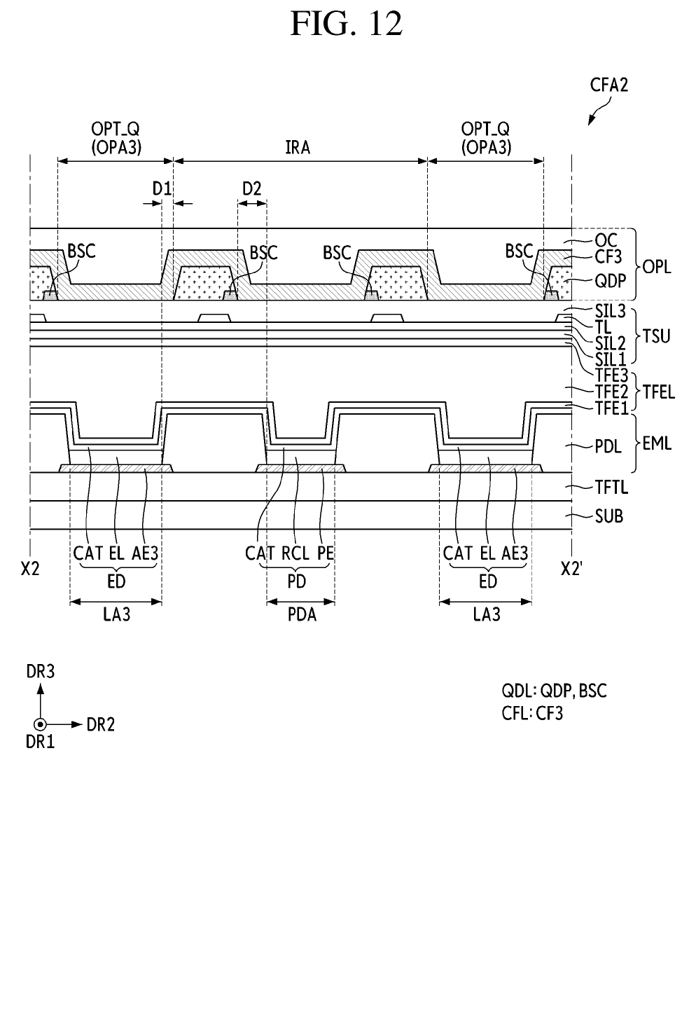

FIG. 11 is a cross-sectional view taken along a line X1-X1' of FIG. 10. FIG. 12 is a cross-sectional view taken along a line X2-X2' of FIG. 10.

Referring to FIGS. 11 and 12 in addition to FIG. 10, the display device 10 may include the substrate SUB, the transistor layer TFTL, the element layer EML, the encapsulation layer TFEL, the touch sensing layer TSU, and the optical layer OPL.

The substrate SUB and the transistor layer TFTL have been described above with reference to FIGS. 7 and 9, and thus the description thereof will be omitted.

The element layer EML may be disposed on the transistor layer TFTL. The element layer EML may include the light-emitting element ED, the light-receiving element PD, and the pixel defining film PDL. The light-emitting element ED and the light-receiving element PD may be disposed in the light-emitting area LA and the sensing area PDA defined by the pixel defining film PDL, respectively. For example, the pixel defining film PDL may have the plurality of openings defined therein, the pixel defining film PDL defining each of the light-emitting area LA and the sensing area PDA.

The light-emitting area LA may include the light-emitting element ED. For example, the first light-emitting area LA1 may include the light-emitting element ED including a first pixel electrode AE1, the second light-emitting area LA2 may include the light-emitting element ED including a second pixel electrode AE2, and the third light-emitting area LA3 may include the light-emitting element ED including a third pixel electrode AE3. Each light-emitting element ED may include each of the pixel electrodes AE1, AE2, and AE3, the light-emitting layer EL, and the common electrode CAT.

The sensing area PDA may include the light-receiving element PD. The light-receiving element PD may include the sensor electrode PE, the light-receiving layer RCL, and the common electrode CAT.

The first pixel electrode AE1, the second pixel electrode AE2, the third pixel electrode AE3, and the sensor electrode PE may be disposed in a corresponding manner to the first to third light-emitting areas LA1, LA2, and LA3 and the sensing area PDA, respectively. The light-emitting layers EL and the light-receiving layer RCL may be disposed in a corresponding manner to the first to third light-emitting areas LA1, LA2, and LA3 and the sensing area PDA, respectively. The common electrode CAT may be commonly disposed across the first to third light-emitting areas LA1, LA2, and LA3 and the sensing area PDA without distinction between the first to third light-emitting areas LA1, LA2, and LA3 and the sensing area PDA.

The encapsulation layer TFEL may be disposed on the common electrode CAT to cover the plurality of light-emitting elements ED and the plurality of light-receiving elements PD. The encapsulation layer TFEL may include at least one inorganic film to prevent oxygen or moisture from penetrating into the element layer EML. The encapsulation layer TFEL may include at least one organic film to protect the element layer EML from foreign substances such as dust.

In an embodiment, the encapsulation layer TFEL may include a first encapsulation layer TFE1, a second encapsulation layer TFE2, and a third encapsulation layer TFE 3. The first encapsulation layer TFE 1 and the third encapsulation layer TFE 3 may be inorganic encapsulation layers, and the second encapsulation layer TFE2 disposed therebetween may be an organic encapsulation layer.

Each of the first encapsulation layer TFE 1 and the third encapsulation layer TFE 3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. The polymer-based material may include an acrylic resin, an epoxy resin, polyimide, polyethylene, and the like. For example, the second encapsulation layer TFE2 may include an acrylic resin, for example, polymethyl methacrylate, polyacrylic acid, or the like. The second encapsulation layer TFE2 may be formed by curing a monomer or applying a polymer.

The touch sensing layer TSU may be disposed on the encapsulation layer TFEL. The touch sensing layer TSU may include a first touch insulating layer SIL1, a second touch insulating layer SIL2, a touch electrode TL, and a third touch insulating layer SIL3.

The first touch insulating layer SIL1 may be disposed on the encapsulation layer TFEL. The first touch insulating layer SIL1 may have insulating and optical functions. The first touch insulating layer SIL1 may include at least one inorganic layer. Optionally, the first touch insulating layer SIL1 may be omitted.

The second touch insulating layer SIL2 may cover the first touch insulating layer SIL1. Although not shown in the drawings, a touch electrode of another layer may be further disposed on the first touch insulating layer SIL1, and the second touch insulating layer SIL2 may cover the touch electrode disposed on the first touch insulating layer SIL1. The second touch insulating layer SIL2 may have insulating and optical functions. For example, the second touch insulating layer SIL2 may be an inorganic film including at least one of a silicon nitride layer, a silicon oxynitride layer, a silicon oxide layer, a titanium oxide layer, and an aluminum oxide layer.

The touch electrode TL may be disposed on the second touch insulating layer SIL2. Each of the touch electrodes TL may not overlap the light-emitting element ED and the light-receiving element PD. For example, the touch electrode TL may overlap the pixel defining film PDL. Each of the touch electrodes TL may be formed as a single layer made of molybdenum (Mo), titanium (Ti), copper (Cu), aluminum (Al), and indium tin oxide (ITO), or may be formed as a stacked structure of aluminum and titanium layers (Ti/Al/Ti), a stacked structure of aluminum and ITO layers (ITO/Al/ITO), an APC alloy layer, and a stacked structure of APC alloy and ITO layers (ITO/APC/ITO).

The third touch insulating layer SIL3 may cover the touch electrode TL and the second touch insulating layer SIL2. The third touch insulating layer SIL3 may have insulating and optical functions. The third touch insulating layer SIL3 may be made of the material as described above with reference to the second touch insulating layer SIL2. In another embodiment, the third touch insulating layer SIL3 may include an organic insulating material such as polyimide.

The optical layer OPL may be disposed on the touch sensing layer TSU. The optical layer OPL may include a light conversion layer QDL, a color filter layer CFL, and an overcoat layer OC.

The light conversion layer QDL may include the light conversion pattern QDP and a light blocking film BSC.

The light conversion pattern QDP may convert the wavelength of light emitted from the light-emitting element ED to emit the light of the converted wavelength again. For example, the light conversion pattern QDP may convert visible light (e.g., blue light) emitted from the third light-emitting area LA3 into infrared light.

The light conversion pattern QDP may include a base resin and a wavelength conversion material. The base resin may include a light-transmissive organic material. For example, the base resin may be made of an epoxy-based resin, an acryl-based resin, a cardo-based resin, an imide-based resin, or the like. The wavelength conversion material may be a quantum dot, a quantum rod, a phosphor, or the like. The quantum dot may include a group IV-based nanocrystal, a group II-VI-based compound nanocrystal, a group III-V-based compound nanocrystal, a group IV-VI-based compound nanocrystal, or a combination thereof. The light conversion pattern QDP may further include a scattering particle that increases wavelength conversion efficiency.

The light conversion pattern QDP may not overlap the light-emitting element ED and the light-receiving element PD in the third direction DR3. For example, the light conversion pattern QDP may overlap the pixel defining film PDL and the touch electrode TL in the third direction DR3.

The opening OPT_Q of the light conversion pattern QDP may overlap the light-emitting element ED. For example, the opening OPT_Q of the light conversion pattern QDP may overlap the third light-emitting area LA3.

An infrared area IRA may be disposed between the openings OPT_Q of the light conversion patterns QDP in the second direction DR2. The infrared area IRA may be an area in which light emitted from the light-emitting element ED is converted into infrared light by the light conversion pattern QDP to emit the infrared light. The infrared area IRA may overlap the sensing area PDA in the third direction DR3.

In some embodiments, a distance D1 in the second direction DR2 between the third light-emitting area LA3 and one end of the light conversion pattern QDP adjacent to the third light-emitting area LA3 may be smaller than a distance D2 in the second direction DR2 between the sensing area PDA and the other end of the light conversion pattern QDP adjacent to the sensing area PDA. That is, in the plan view illustrated in FIG. 10, a distance in the second direction DR2 between an outer circumference of the third light-emitting area LA3 and an outer circumference of the opening OPT_Q of the light conversion pattern QDP may be smaller than a distance in the second direction DR2 between the sensing area PDA and the light conversion pattern QDP.

The light blocking film BSC may include a light absorbing material. For example, the light blocking film BSC may include an inorganic black pigment or an organic black pigment. The inorganic black pigment may be carbon black, and the organic black pigment may include at least one of lactam black, perylene black, and aniline black. However, embodiments of the present disclosure are not limited thereto. In some embodiments, the light blocking film BSC may absorb light having a visible wavelength and transmit light having an infrared wavelength.

The light blocking film BSC may prevent light emitted from the light-emitting element ED and then incident on the light conversion pattern QDP from being emitted from the light conversion pattern QDP in a wavelength-maintained state in which the wavelength is not converted by the light conversion pattern QDP, and thus from being incident on the sensing area PDA.

The light blocking film BSC may be disposed at an edge of the light conversion pattern QDP which is adjacent to the sensing area PDA. For example, as illustrated in FIG. 12, a portion of the light blocking film BSC disposed on a left side of the sensing area PDA may be disposed at a right edge of the light conversion pattern QDP, while a portion of the light blocking film BSC disposed on a right side of the sensing area PDA may be disposed at a left edge of the light conversion pattern QDP.

The color filter layer CFL may be disposed on the touch sensing layer TSU and the light conversion layer QDL. The color filter layer CFL may include a first color filter CF1, a second color filter CF2, and a third color filter CF3.

Each of the first to third color filters CF1, CF2, and CF3 may include colorants such as dyes or pigments that absorb light in wavelength bands other than that of light in a specific wavelength band, and may be disposed in a corresponding manner to the color of light emitted from the light-emitting element including the light-emitting area LA. For example, the first color filter CF1 may be a red color filter disposed to overlap the first light-emitting area LA1 and transmitting only the red light as the first light. The second color filter CF2 may be a green color filter disposed to overlap the second light-emitting area LA2 and transmitting only the second light of the green color, and the third color filter CF3 may be a blue color filter disposed to overlap the third light-emitting area LA3 and transmitting only the third light of blue color.

At least a portion of the third color filter CF3 may be disposed in the infrared area IRA. Accordingly, in some embodiments, in order to increase the amount of infrared rays incident on the light-receiving element PD, at least a portion of the third color filter CF3 may have a high transmittance of the infrared rays.

Each of the first to third color filters CF1, CF2, and CF3 may be disposed in a corresponding manner to each of the plurality of light-emitting areas LA. At least a portion of each of the plurality of color filters CF1, CF2, and CF3 may overlap each of the plurality of light-emitting areas LA. For example, at least a portion of the first color filter CF1 may overlap the first light-emitting area LA1, at least a portion of the second color filter CF2 may overlap the second light-emitting area LA2, and at least a portion of the third color filter CF3 may overlap the third light-emitting area LA3.

The color filter layer CFL may include a first light-transmissive area OPA1, a second light-transmissive area OPA2, a third light-transmissive area OPA3, and a light blocking area BMA.

The first light-transmissive area OPA1 may be an area in which only the first color filter CF1 is disposed and the second color filter CF2 and the third color filter CF3 are not disposed. The second light-transmissive area OPA2 may be an area in which only the second color filter CF2 is disposed and the first color filter CF1 and the third color filter CF3 are not disposed. The third light-transmissive area OPA3 may be an area in which only the third color filter CF3 is disposed and the first color filter CF1 and the second color filter CF2 are not disposed. The light blocking area BMA may be an area in which all of the first, second, and third color filters CF1, CF2, and CF3 overlap.

The first light-transmissive area OPA1 may overlap the first light-emitting area LA1, and may transmit only the red light as the first light. The second light-transmissive area OPA2 may overlap the second light-emitting area LA2 and may transmit only the green light as the second light. The third light-transmissive area OPA3 may overlap the third light-emitting area LA3, and may transmit only the blue light as the third light. In some embodiments, the third light-transmissive area OPA3 may overlap the opening OPT_Q of the light conversion pattern QDP.

The first light-transmissive area OPA1, the second light-transmissive area OPA2, and the light blocking area BMA may be disposed in the first area CFA1, and the third light-transmissive area OPA3 and the infrared ray area IRA may be disposed in the second area CFA2.

In some embodiments, the light conversion pattern QDP (or the light conversion layer QDL) may not be disposed in the first area CFA1. The light conversion pattern QDP (or the light conversion layer QDL) may be disposed in the second area CFA2.

Accordingly, in the first area CFA1, the touch sensing layer TSU may directly contact the color filter layer CFL (e.g., the first color filter CF1 and the second color filter CF2). In the second area CFA2, the touch sensing layer TSU may directly contact the color filter layer CFL (e.g., the third color filter CF3) and the light conversion layer QDL (e.g., the light conversion pattern QDP).

The overcoat layer OC may be disposed on the color filter layer CFL. The overcoat layer OC may be disposed over an entirety of a surface of the display area DA to planarize an upper surface of the display panel 100. The overcoat layer OC may be a colorless light-transmissive layer that does not have a color in a visible light band. For example, the overcoat layer OC may include a colorless light-transmissive organic material such as an acrylic resin. However, embodiments of the present disclosure are not limited thereto. In some embodiments, the overcoat layer OC may have a high transmittance of the infrared light.

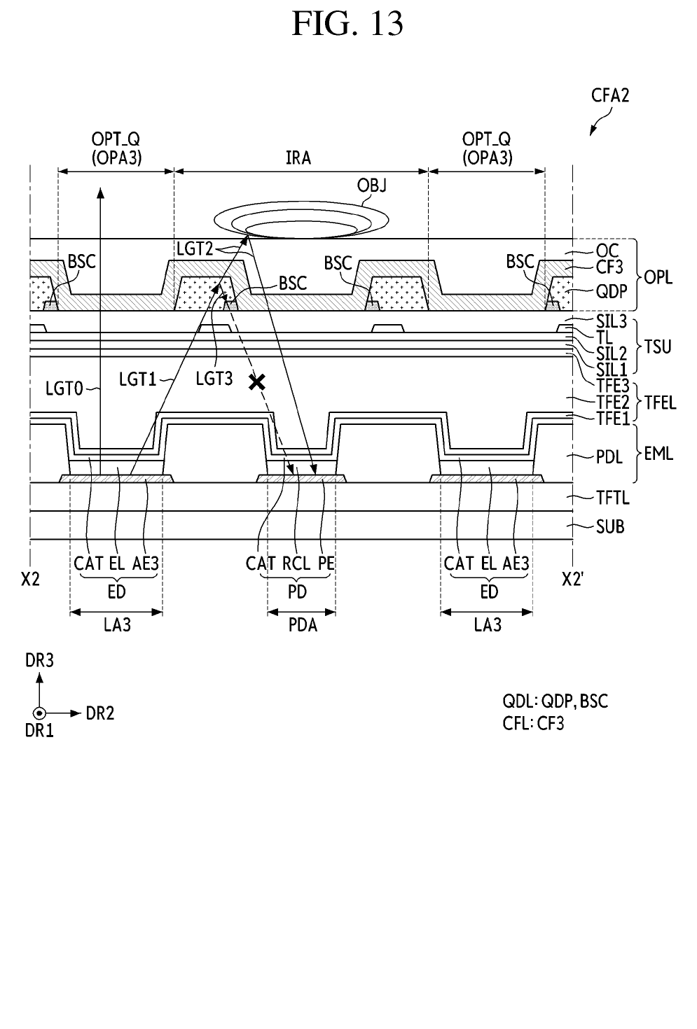

Operation of the display device 10 will be described with reference to FIG. 13.

FIG. 13 is a cross-sectional view illustrating an operation of the display device according to the embodiment of FIG. 10.

Referring to FIG. 13 in addition to FIGS. 10 to 12, first visible light LGT0 emitted from the third light-emitting area LA3 may travel through the third light-transmissive area OPA3 to the outside. For example, the first visible light LGT0 emitted from the third light-emitting area LA3 may be blue light and then may pass through the third color filter CF3 as a blue color filter, and be emitted to the outside.

Second visible light LGT1 emitted from the third light-emitting area LA3 may be incident on the light conversion pattern QDP. A portion of the second visible light LGT1 may be converted into first infrared light LGT2 by the light conversion pattern QDP. The first infrared light LGT2 may be reflected from an object OBJ located in the infrared area IRA. The first infrared light LGT2 reflected from the object OBJ may be incident on the sensing area PDA and sensed by the sensing pixel.

Some of the second visible light LGT1 incident on the light conversion pattern QDP may not be converted into infrared light. In this case, third visible light LGT3 that includes the non-converted portion may be blocked by the light blocking film BSC and thus may not be incident on the sensing area PDA.

Meanwhile, a portion of the first infrared light LGT2 obtained via the light conversion of the light conversion pattern QDP may be emitted to the outside without being reflected from the object OBJ. In this regard, the first infrared light LGT2 is infrared light rather than visible light and thus may not be visible to the user.

The display device 10 according to the present embodiment may include the light-receiving element PD capable of sensing the infrared light, and thus may perform a sensing function using light not recognized by the user. In addition, the sensing is performed using the infrared light, and thus noise is smaller than that in using the visible light, such that the sensing accuracy may be improved.

In one example, the display device 10 according to the present embodiment includes the light conversion layer QDL, and thus may use a visible light-emitting element included in the light-emitting pixel PX of the display device 10 as a light source without including a separate infrared light-emitting element. Therefore, an area for providing a separate infrared light-emitting element does not need to be provided such that the high resolution display device 10 may be implemented.

Hereinafter, further embodiments of a display device according to an embodiment will be described. In the following embodiments, the same components as those of the previously described embodiments are denoted as the same reference numerals, and redundant descriptions thereof are omitted or simplified, and differences will be mainly described.

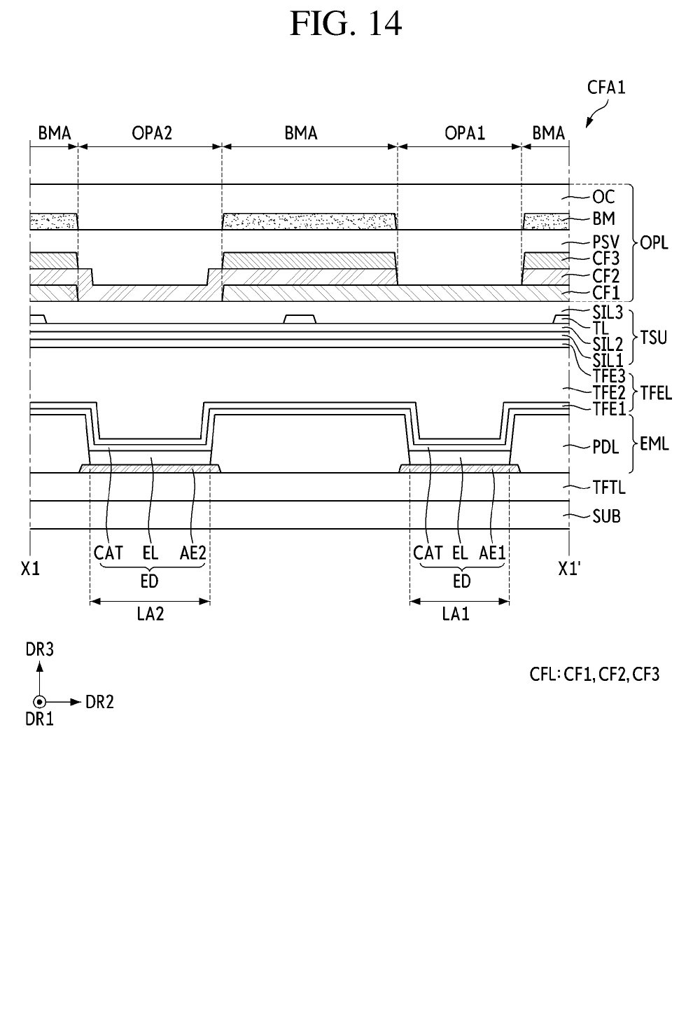

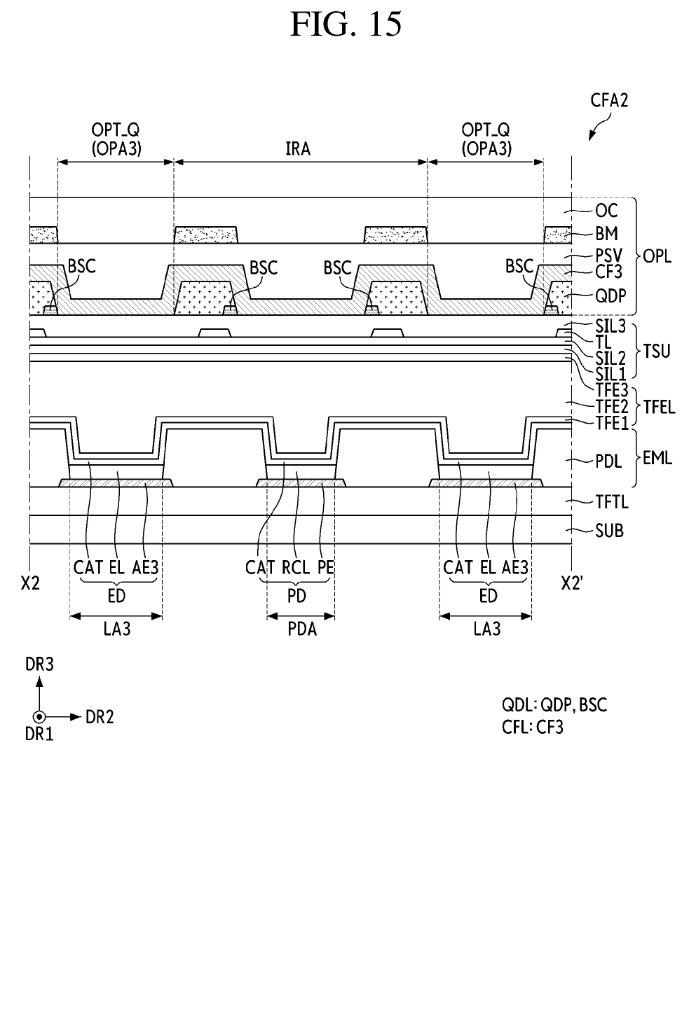

FIG. 14 is a cross-sectional view taken along a line X1-X1' of FIG. 10 in a display device according to another embodiment. FIG. 15 is a cross-sectional view taken along a line X2-X2' of FIG. 10 in a display device according to another embodiment.

Referring to FIGS. 14 and 15 in addition to FIG. 10, the display device 10 according to the present embodiment is different from the display device 10 according to the embodiment as described in that the optical layer OPL further includes a light blocking layer BM.

More specifically, the optical layer OPL may further include a planarization layer PSV and the light blocking layer BM.

The planarization layer PSV may be disposed on the color filter layer CFL. The planarization layer PSV may be disposed over the entirety of the surface of the display area DA to planarize the upper surface of the color filter layer CFL. The planarization layer PSV may be a colorless light-transmissive layer that does not have a color in a visible light band. For example, the planarization layer PSV may include a colorless light-transmissive organic material such as an acrylic resin. However, embodiments of the present disclosure are not limited thereto. In some embodiments, the planarization layer PSV may have a high transmittance of the infrared light.

The light blocking layer BM may be disposed on the planarization layer PSV. The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black. However, embodiments of the present disclosure are not limited thereto. In some embodiments, the light blocking layer BM may absorb light having a visible wavelength and may transmit light having an infrared wavelength.

The light blocking layer BM may include light blocking patterns, and the light blocking patterns may overlap the pixel defining film PDL and the light conversion patterns QDP. The light blocking layer BM may have light-transmissive openings defined therein, each being disposed between light blocking patterns, and each of the light-transmissive openings may overlap each of the first to third light-transmissive areas OPA1, OPA2, and OPA3. The light-transmissive openings may overlap the light-emitting element ED and the light-receiving element PD.

Further, in the present embodiment, the overcoat layer OC may be disposed on the light blocking layer BM and the planarization layer PSV.

The display device 10 according to the present embodiment may further include the light blocking layer BM, thereby preventing color mixing between the adjacent light-emitting areas LA and the noise in the sensing area PDA.

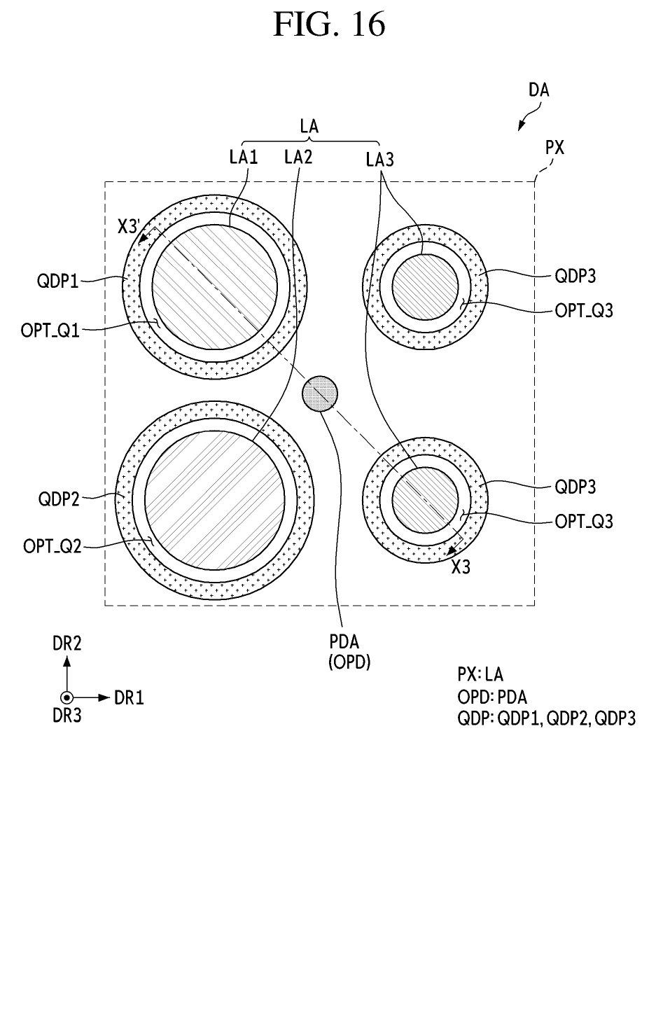

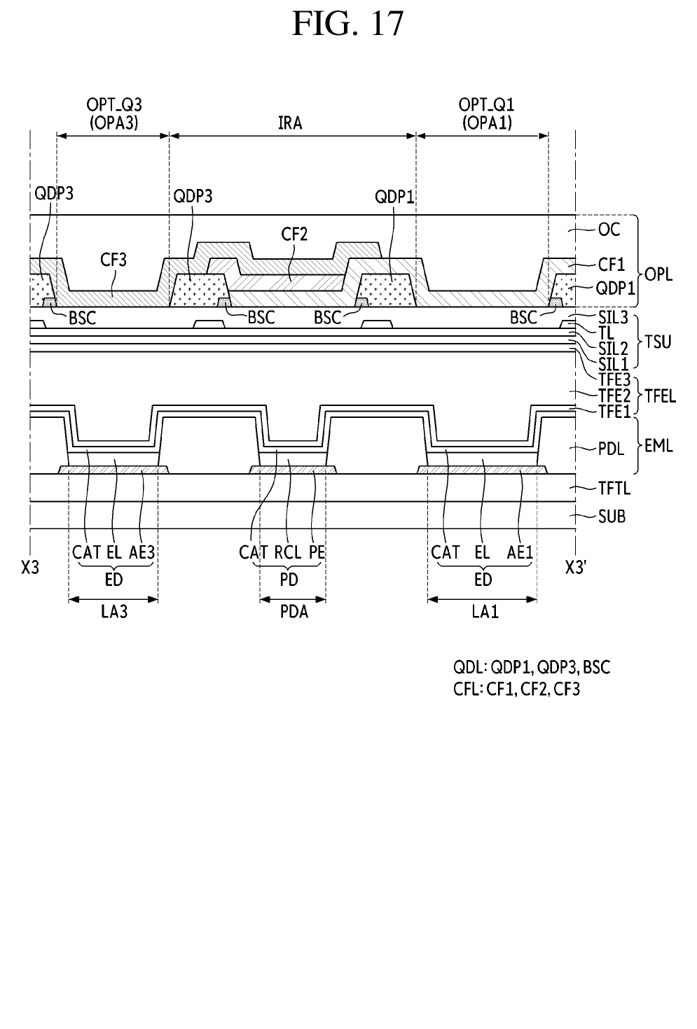

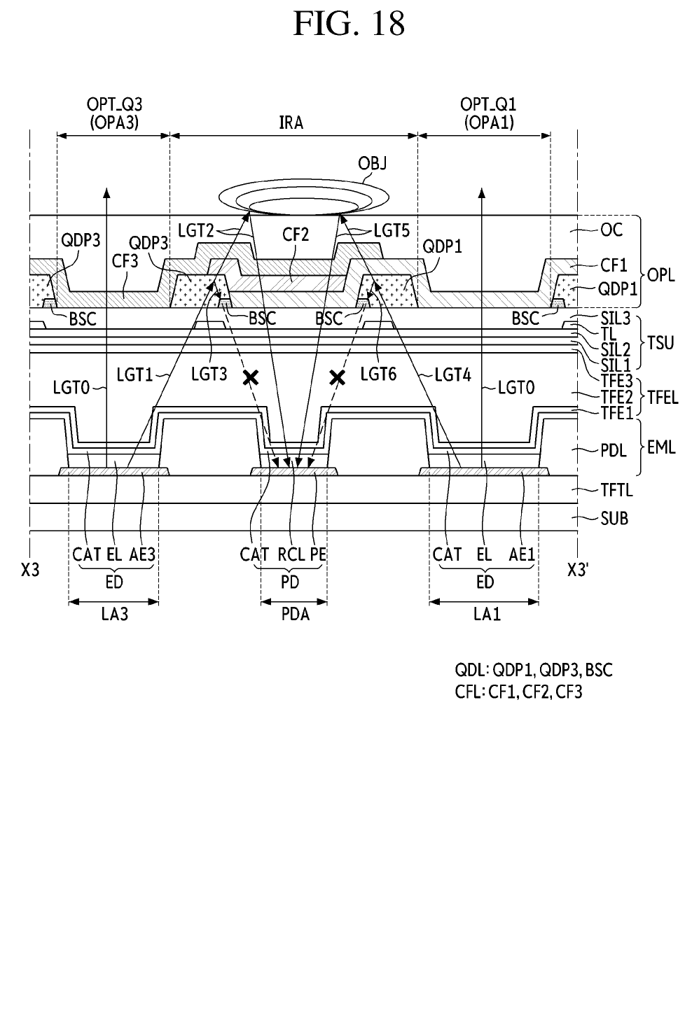

FIG. 16 is a plan view illustrating a portion of a display area of a display device according to still another embodiment. FIG. 17 is a cross-sectional view taken along a line X3-X3' of FIG. 16. FIG. 18 is a cross-sectional view illustrating an operation of the display device according to the embodiment of FIG. 16.

Embodiments of the display device 10 disclosed in FIGS. 16 to 18 may differ from the display device 10 that is described above with reference to FIG. 10, etc. in terms of an arrangement of the light conversion pattern QDP and the sensing area PDA.

More specifically, the sensing area PDA may be between the first light-emitting area LA1 and the third light-emitting area LA3 and between the second light-emitting area LA2 and another third light-emitting area LA3 instead of just between two third light-emitting areas LA3. The sensing area PDA may be disposed between two light-emitting areas LA in a diagonal direction, or a direction that is diagonal to the first direction DR1 and the second direction DR2, and be spaced apart from the light-emitting areas LA. For example, the sensing area PDA may be disposed on one side of the second light-emitting area LA2 in a diagonal direction, may be disposed on one side of the third light-emitting area LA3 in a diagonal direction, may be disposed on one side of the first light-emitting area LA1 in a diagonal direction, and may be disposed on one side of the third light-emitting area LA3 in a diagonal direction. In the example of FIG. 16, the sensing area PDA may be located to the bottom right of the first light-emitting area LA1, to the upper right of the second light-emitting area LA2, to the bottom left of one third light-emitting area LA3, and to the upper left of another third light-emitting area LA3. In one embodiment, the sensing area PDA may be positioned at the intersection of a first line extending between the center of the first light-emitting area LA1 and the center of one of the third light-emitting area LA3 and a second line extending between the center of the second light-emitting area LA2 and the center of another one of the third light-emitting area LA3, in plan view.

The light conversion pattern QDP may include a first light conversion pattern QDP1, a second light conversion pattern QDP2, and a third light conversion pattern QDP3. The first light conversion pattern QPD1 may surround the first light-emitting area LA1, the second light conversion pattern QPD2 may surround the second light-emitting area LA2, and the third light conversion pattern QPD 3 may surround the third light-emitting area LA3.

The first light conversion pattern QDP1 may convert the visible light of the red wavelength emitted from the first light-emitting area LA1 into infrared light, the second light conversion pattern QDP2 may convert the visible light of the green wavelength emitted from the second light-emitting area LA2 into infrared light, and the third light conversion pattern QDP3 may convert the visible light of the blue wavelength emitted from the third light-emitting area LA3 into infrared light. The light of the infrared wavelength converted by each of the first to third light conversion patterns QDP1, QDP2, and QDP3 may be sensed by the light-receiving element PD of the sensing area PDA.

The first light conversion pattern QDP1 may include a first opening OPT_Q1 located approximately at the center of the first light conversion pattern QDP1, the second light conversion pattern QDP2 may include a second opening OPT_Q2 located approximately at the center of the second light conversion pattern QDP2, and the third light conversion pattern QDP3 may include a third opening OPT_Q3 located approximately at a center of the third light conversion pattern QDP3.

The size of the first opening OPT_Q1 in a plan view may be greater than the size of the first light-emitting area LA1 in a plan view. The size of the second opening OPT_Q 2 in a plan view may be greater than the size of the second light-emitting area LA2 in a plan view. The size of the third opening OPT_Q3 in a plan view may be greater than the size of the third light-emitting area LA3 in a plan view.

An inner side surface of the first light conversion pattern QDP1 may be located outside of an outer circumference of the first light-emitting area LA1. An inner side surface of the second light conversion pattern QDP2 may be located outside of an outer circumference of the second light-emitting area LA2. An inner side surface of the third light conversion pattern QDP3 may be located outside of an outer circumference of the third light-emitting area LA3.

The light conversion layer QDL may include first to third light conversion patterns QDP1, QDP2, and QDP3.

The first to third light conversion patterns QDP1, QDP2, and QDP3 may not overlap the light-emitting element ED and the light-receiving element PD in the third direction DR3. For example, the first to third light conversion patterns QDP1, QDP2, and QDP3 may overlap the pixel defining film PDL and the touch electrode TL in the third direction DR3.

The first opening OPT_Q1 of the first light conversion pattern QDP1 may overlap the first light-emitting area LA1, the second opening OPT_Q2 of the second light conversion pattern QDP2 may overlap the second light-emitting area LA2, and the third opening OPT_Q3 of the third light conversion pattern QDP3 may overlap the third light-emitting area LA3.

The infrared area IRA may be disposed between the first opening OPT_Q1 of the first light conversion pattern QDP1 and the third opening OPT_Q3 of the third light conversion pattern QDP3. Although not shown in the drawings, the infrared area IRA may also be disposed between the second opening OPT_Q2 of the second light conversion pattern QDP2 and the third opening OPT_Q3 of the third light conversion pattern QDP3. The infrared area IRA may be an area in which light emitted from the light-emitting element ED is converted into infrared light by each of the first to third light conversion patterns QDP1, QDP2, and QDP3 to emit infrared light. The infrared area IRA may overlap the sensing area PDA in the third direction DR3.

The light blocking film BSC (see FIG. 17) may be disposed at an edge of the light conversion pattern QDP, which is adjacent to the sensing area PDA. For example, as illustrated in FIG. 17, a portion of the light blocking film BSC disposed on the left side of the sensing area PDA may be disposed at a right edge of the third light conversion pattern QDP3, while a portion of the light blocking film BSC disposed on the right side of the sensing area PDA may be disposed at the left edge of the first light conversion pattern QDP1.

In the infrared area IRA, the first to third color filters CF1, CF2, and CF3 may be disposed so as to be stacked sequentially. Accordingly, visible light may not be emitted from the infrared area IRA, and only infrared light may be emitted. In order to increase the amount of infrared rays incident on the light-receiving element PD, in some embodiments, each of the first to third color filters CF1, CF2, and CF3 may have high transmittance of the infrared light.

In some embodiments, the first light-transmissive area OPA1 may overlap the first opening OPT_Q1 of the first light conversion pattern QDP1, and the third light-transmissive area OPA3 may overlap the third opening OPT_Q3 of the third light conversion pattern QDP3. Although not shown in the drawings, the second light-transmissive area OPA2 may overlap the second opening OPT_Q2 of the second light conversion pattern QDP2.

As illustrated in FIG. 18, the first visible light LGT0 emitted from each of the first light-emitting area LA1 and the third light-emitting area LA3 may pass through each of the first light-transmissive area OPA1 and the third light-transmissive area OPA3 and be emitted to the outside. For example, the first visible light LGT0 emitted from the first light-emitting area LA1 may be red light, may transmit through the first color filter CF1 as a red color filter, and may be emitted to the outside. The first visible light LGT0 emitted from the third light-emitting area LA3 may be blue light, and may transmit through the third color filter CF3 as a blue color filter, and may be emitted to the outside.

The second visible light LGT1 emitted from the third light-emitting area LA3 may be incident on the third light conversion pattern QDP3. A portion of the second visible light LGT1 may be converted into the first infrared light LGT2 by the third light conversion pattern QDP3. The first infrared light LGT2 may be reflected from the object OBJ located in the infrared area IRA. The first infrared light LGT2 reflected from the object OBJ may be incident on the sensing area PDA and sensed by the sensing pixel.

A portion of the second visible light LGT1 incident on the third light conversion pattern QDP3 may not be converted into infrared light. In this case, the third visible light LGT3 as the unconverted portion may be blocked with the light blocking film BSC and may not be incident on the sensing area PDA.

The fourth visible light LGT4 emitted from the first light-emitting area LA1 may be incident on the first light conversion pattern QDP1. A portion of the fourth visible light LGT4 may be converted into the second infrared light LGT5 by the first light conversion pattern QDP1. The second infrared light LGT5 may be reflected from the object OBJ located in the infrared area IRA. The second infrared light LGT 5 reflected from the object OBJ may be incident on the sensing area PDA and sensed by the sensing pixel.

Some of the fourth visible light LGT 4 is incident on the first light conversion pattern QDP1 may not be converted into infrared light. In this case, the non-converted portion, shown as the sixth visible light LGT6, may be blocked with the light blocking film BSC and may not be incident on the sensing area PDA.

Meanwhile, some of the first infrared light LGT2 obtained via the conversion of each of the first and third light conversion patterns QDP1 and QDP3 may be emitted to the outside without being reflected by the object OBJ. The first infrared light LGT2 is not in the visible light wavelength range and thus may not be visible to the user.

Alternatively, visible light that is not incident on the first and third light conversion patterns QDP1 and QDP3 may be blocked by the first, second, and third color filters CF1, CF2, and CF3 located in the infrared area IRA and may not be visually recognized by the user.

The display device 10 according to the present embodiment includes the light-receiving element PD capable of sensing infrared light, and thus may perform a sensing function using light that is not visually recognized by a user. In addition, the sensing is performed using the infrared light, and thus noise is reduced compared to when visible light is used. This way, sensing accuracy may be improved.

In one example, the display device 10 according to the present embodiment includes the light conversion layer QDL, and thus may use a visible light-emitting element included in the light-emitting pixel PX of the display device 10 as a light source without including a separate infrared light-emitting element. Therefore, an area for providing a separate infrared light-emitting element does not need to be provided such that the high resolution display device 10 may be implemented.

The display device 10 according to the above-described embodiments may be applied to various electronic devices 1. The electronic device 1 according to an embodiment may include the above-described display device 10, and may further include a module or a device having an additional function other than the display device 10.

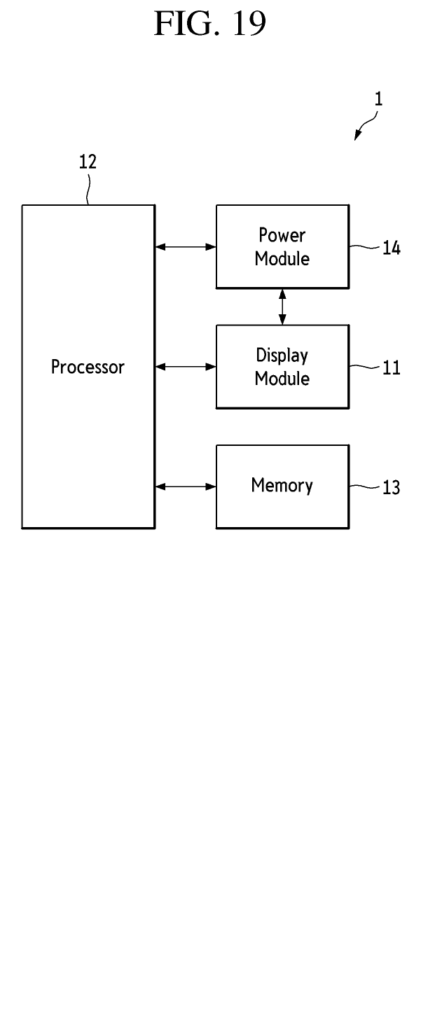

FIG. 19 is a block diagram of an electronic device according to an embodiment.

Referring to FIG. 19, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for the operation of the processor 12 or the display module 11 may be stored in the memory 13. When the processor 12 executes an application stored in the memory 13, an image data signal and/or an input control signal may be transmitted to the display module 11, and the display module 11 may process the received signal to output image information on a display screen.

The power module 14 may include a power supply module such as a power adapter or a battery device, and a power conversion module that converts power supplied from the power supply module to generate power required for the operation of the electronic device 1.

At least one of the above-described components of the electronic device 1 may be included in the display device 10 according to the above-described embodiments. In addition, in a terms of a function, a portion of an individual module included in one module may be included in the display device 10, and the other portion thereof may be provided separately from the display device 10. For example, the display device 10 may include the display module 11, and the processor 12, the memory 13, and the power module 14 may be provided in the form of other devices in the electronic device 1 rather than the display device 10.

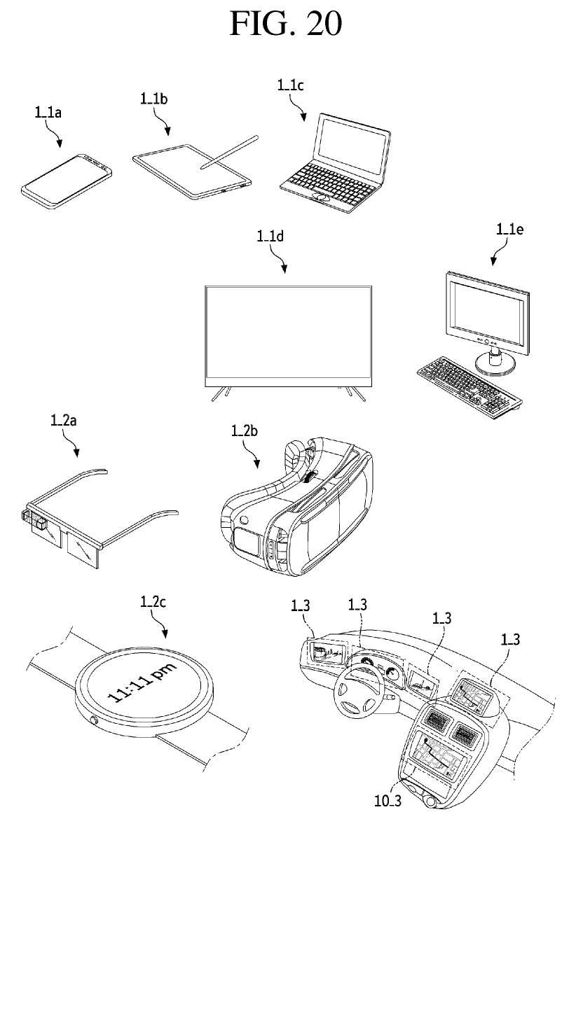

FIG. 20 is a schematic diagram of an electronic device according to various embodiments.

Referring to FIG. 20, various electronic devices 1 to which the display device 10 according to embodiments is applied include an electronic device 1_1 for image display, such as a smartphone 1_1a, a tablet PC 1_1b, a laptop 1_1c, a TV 1_1d, and a desktop monitor 1_1e, a wearable electronic device 1_2 including a display module such as smart glasses 1_2a, a head mounted display 1_2b, and a smart watch 1_2c, and an electronic device 1_3 for a vehicle including a display module such as a dashboard, a center fascia, a center information display (CID) disposed on a dashboard, and a room mirror display of a vehicle.

Features of various embodiments of the disclosure may be combined partially or in whole. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without substantially departing from the principles of the invention. Therefore, the disclosed embodiments of the invention are used in a generic and descriptive sense and not for purposes of limitation.

What is claimed is:

1. A display device comprising:
a substrate;
a circuit layer disposed on the substrate;
an element layer disposed on the circuit layer, wherein the element layer includes a light-emitting element configured to emit first light having a first wavelength, a light-receiving element configured to sense second light having a second wavelength, and a pixel defining film patterned to define each of the light-emitting element and the light-receiving element; and
a light conversion layer disposed on the element layer and including a light conversion pattern overlapping the pixel defining film,
wherein the light conversion pattern converts the first light emitted from the light-emitting element into the second light,
wherein the light-receiving element is positioned to receive and sense the second light.

2. The display device of claim 1, wherein the light conversion pattern is disposed to surround the light-emitting element in a plan view of the display device.

3. The display device of claim 1, wherein at least a portion of the light conversion pattern is disposed between the light-emitting element and the light-receiving element in a plan view of the display device.

4. The display device of claim 1, wherein the light conversion pattern has an opening defined therein above the light-emitting element.

5. The display device of claim 4, wherein a size of the opening is larger than a size of the light-emitting element in plan view.

6. The display device of claim 4, further comprising a color filter disposed on the light conversion layer and transmitting the first light,
wherein a first portion of the color filter overlaps the opening and the light-emitting element.

7. The display device of claim 6, wherein a second portion of the color filter overlaps the light-receiving element and transmits the second light.

8. The display device of claim 1, wherein a distance between one end of the light conversion pattern and the light-emitting element is smaller than a distance between the other end of the light conversion pattern and the light-receiving element.

9. The display device of claim 1, wherein the light conversion layer includes a light blocking film constructed to absorb or block the first light,
wherein the light blocking film is disposed at one end of the light conversion pattern adjacent to the light-receiving element.

10. The display device of claim 1, wherein the light conversion pattern includes a base resin and a wavelength conversion material,
wherein the wavelength conversion material includes at least one of a quantum dot, a quantum rod, and phosphor.

11. The display device of claim 1, further comprising a light blocking layer disposed on the light conversion layer and having light-transmissive openings defined therein,
wherein each of the light-transmissive openings is positioned above one of the light-emitting element and the light-receiving element.

12. The display device of claim 1, wherein the first light is visible light and the second light is infrared light.

13. A display device comprising:
a substrate;
a circuit layer disposed on the substrate;
an element layer disposed on the circuit layer, wherein the element layer includes:
a first light-emitting element configured to emit first light having a first wavelength;
a second light-emitting element configured to emit second light having a second wavelength;
a third light-emitting element configured to emit third light having a third wavelength;
a light-receiving element configured to sense fourth light having a fourth wavelength; and
a pixel defining film patterned to define each of the first, second, and third light-emitting elements and the light-receiving element; and
a light conversion layer disposed on the element layer and including a first light conversion pattern overlapping the pixel defining film,
wherein the first light conversion pattern is disposed to surround the first light-emitting element in a plan view of the display device,
wherein the first light conversion pattern converts the first light emitted from the first light-emitting element into the fourth light,
wherein the light-receiving element is positioned to receive and sense the fourth light obtained via light conversion of the first light conversion pattern.

14. The display device of claim 13, wherein the light conversion layer further includes at least one of a second light conversion pattern or a third light conversion pattern overlapping the pixel defining film,
wherein the second light conversion pattern is disposed to surround the second light-emitting element in the plan view,
wherein the third light conversion pattern is disposed to surround the third light-emitting element in the plan view,
wherein the second light conversion pattern is constructed to convert the second light emitted from the second light-emitting element into the fourth light,
wherein the third light conversion pattern is constructed to convert the third light emitted from the third light-emitting element into the fourth light,
wherein the light-receiving element is positioned to receive and sense the fourth light obtained via light conversion of at least one of the second light conversion pattern or the third light conversion pattern.

15. The display device of claim 14, wherein the first to third light conversion patterns include first to third openings overlapping the first to third light-emitting elements, respectively.

16. The display device of claim 14, further comprising:
a first color filter disposed on the light conversion layer and transmitting the first light ;
a second color filter disposed on the light conversion layer and transmitting the second light; and
a third color filter disposed on the light conversion layer and transmitting the third light ,
wherein at least a portion of each of the first to third color filters overlaps the light-receiving element.

17. The display device of claim 13, wherein the display device includes:
a first area in which the first light-emitting element and the light-receiving element are disposed; and
a second area in which the second light-emitting element and the third light-emitting element are disposed,
wherein the first light conversion pattern is disposed in the first area and is absent in the second area.

18. The display device of claim 17, further comprising:
a first color filter disposed on the light conversion layer and transmitting the first light;
a second color filter disposed on the light conversion layer and transmitting the second light; and
a third color filter disposed on the light conversion layer and transmitting the third light ,
wherein in the first area, the first color filter overlaps the first light-emitting element and the light-receiving element,
wherein in the second area, the second color filter overlaps the second light-emitting element, and the third color filter overlaps the third light-emitting element.

19. The display device of claim 13, wherein each of the first, second, and third light is visible light, and the fourth light is infrared light.

20. An electronic device comprising:
a display device for displaying an image;
a processor configured to provide an image driving signal to the display device; and
a power module configured to supply power to the display device and the processor,
wherein the display device includes:
a substrate;
a circuit layer disposed on the substrate;
an element layer disposed on the circuit layer, wherein the element layer includes a light-emitting element configured to emit first light having a first wavelength, a light-receiving element positioned to receive and sense second light having a second wavelength, and a pixel defining film patterned to define each of the light-emitting element and the light-receiving element; and
a light conversion layer disposed on the element layer and including a light conversion pattern overlapping the pixel defining film,
wherein the light conversion pattern converts the first light emitted from the light-emitting element into the second light,
wherein the light-receiving element is positioned to receive and sense the second light.
